(19) United States
(12) Patent Application Publication
(10) Pub. No.: US 2025/0053084 A1
(43) Pub. Date: Feb. 13, 2025

(54) DEVELOPMENT OF HYBRID ORGANOTIN OXIDE PHOTORESISTS

(71) Applicant: Lam Research Corporation, Fremont, CA (US)

(72) Inventors: Eric Calvin Hansen, San Jose, CA (US); Chenghao Wu, San Jose, CA (US); Timothy William Weidman, Sunnyvale, CA (US)

(21) Appl. No.: 18/718,530

(22) PCT Filed: Dec. 12, 2022
(86) PCT No.: PCT/US2022/081376

§ 371 Date: Jun. 11, 2024

Related U.S. Application Data
(60) Provisional application No. 63/265,354, filed on Dec. 13, 2021.

(51) Int. Cl. G03F 7/004; G03F 7/16; G03F 7/20; G03F 7/36

(52) U.S. Cl. CPC G03F 7/0042; G03F 7/16; G03F 7/2004; G03F 7/36

(57) ABSTRACT

The present disclosure relates to a film formed with an organometallic precursor and an organic co-reactant, as well as methods for forming and employing such films. In particular embodiments, the films can be incubated after exposure to radiation, which can provide enhanced material differences between the exposed and unexposed regions. In non-limiting embodiments, the radiation can include extreme ultraviolet (EUV) or deep ultraviolet (DUV) radiation.

### INCORPORATION BY REFERENCE

A PCT Request Form is filled concurrently with this specification as part of the present application. Each application that the present application claims benefit of or priority to as identified in the concurrently filed PCT Request Form is incorporated by reference herein its entirety and for all purposes.

### FIELD

The present disclosure relates to a film formed with an organometallic precursor and an organic co-reactant, as well as methods for forming and employing such films. In particular embodiments, the films can be incubated after exposure to radiation, which can provide enhanced material differences between the exposed and unexposed regions. In non-limiting embodiments, the radiation can include extreme ultraviolet (EUV) or deep ultraviolet (DUV) radiation.

### BACKGROUND

The background description provided herein is for the purpose of generally presenting the context of the present technology. Work of the presently named inventors, to the extent it is described in this background section, as well as aspects of the description that may not otherwise qualify as prior art at the time of filing, are neither expressly nor impliedly admitted as prior art against the present technology.

Patterning of thin films in semiconductor processing is often an important step in the fabrication of semiconductors. Patterning involves lithography. In photolithography, such as 193 nm photolithography, patterns are printed by emitting photons from a photon source onto a mask and printing the pattern onto a photosensitive photoresist, thereby causing a chemical reaction in the photoresist that, after development, removes certain portions of the photoresist to form the pattern.

Advanced technology nodes (as defined by the International Technology Roadmap for Semiconductors) include nodes 22 nm, 16 nm, and beyond. In the 16 nm node, for example, the width of a via or line in a Damascene structure can be no greater than about 30 nm. Scaling of features on advanced semiconductor integrated circuits (ICs) and other devices is driving lithography to improve resolution.

Extreme ultraviolet (EUV) lithography can extend lithography technology by moving to smaller imaging source wavelengths than would be achievable with photolithography methods. EUV light sources at approximately 10-20 nm, or 11-14 nm wavelength, for example 13.5 nm wavelength, can be used for leading-edge lithography tools, also referred to as scanners. EUV radiation is strongly absorbed in a wide range of solid and fluid materials including quartz and water vapor, and so operates in a vacuum.

### SUMMARY

The present disclosure relates to use of an organic co-reactant with an organometallic precursor to provide a patterning radiation-sensitive film. In one instance, the precursor can be an organometallic compound that can be deposited to provide a metal-containing photoresist, and the organic co-reactant can be employed to interact with the precursor during deposition. Such an interaction may not result in deposition of the organic co-reactant within the film but may nonetheless influence the composition or properties of the film.

In another instance, the precursor can be an organometallic compound that can be deposited to provide a metal-containing photoresist, and the organic co-reactant can be employed to react with the precursor during deposition. Such a reaction can provide a modified precursor that can be deposited within the film. Furthermore, the modified precursor can possess a radiation-responsive organic moiety provided by the organic co-reactant and a radiation-sensitive metal center provided by the precursor. In non-limiting embodiments, the radiation can include extreme ultraviolet (EUV) or deep ultraviolet (DUV) radiation.

Use of such organometallic precursors with organic co-reactants can provide a film, which in turn can be incubated under conditions to provide enhanced material differences between the exposed and unexposed regions. Such post-exposure incubation can improve the sensitivity of the film to a particular radiation dose. For instance, an incubated film can have a lower dose-to-clear (DtC) or dose-to-gel (DtG) or dose-to-size (DtS), as compared to an exposed film (that has not been incubated). In this way, the same underlying film can be optimized for high- or low-dose applications by tuning the incubation condition. Non-limiting incubation conditions include control of temperature, atmosphere, humidity, and/or time periods, as described herein.

Furthermore, by introducing this incubation step, a variety of different developers can be selected to distinguish between the lithographically exposed and unexposed areas. In one non-limiting instance, the selection of a particular incubation condition allowed for development with pH neutral water and with a reduced DtG threshold. Other developers may be used, such as aqueous solutions, organic solutions, or gaseous acids, as described herein.

In particular embodiments, the method includes a selection of particular incubation conditions and particular types of developers to achieve a desired functionality of the film. In this way, the same film can be employed for different applications by tuning the incubation conditions and developer conditions, which implies great flexibility of the material for different lithographic applications (e.g., for high-dose, low roughness applications as well as low-dose, high-throughput applications). Furthermore, differing types and combinations of one or more organometallic precursors and one or more organic co-reactants can be employed to tune the composition of the deposited film.

Accordingly, in a first aspect, the present disclosure encompasses a method of employing a resist, the method including: providing an organometallic precursor in the presence of an organic co-reactant to a surface of a substrate to provide a resist film; patterning the resist film by exposure to patterned radiation, thereby providing an exposed film having radiation exposed areas and radiation unexposed areas; incubating the exposed film at a temperature of about 20-300° C., thereby providing an incubated film; and developing the incubated film, thereby removing the radiation exposed areas to provide a pattern within a positive tone resist film or removing the radiation unexposed areas to provide a pattern within a negative tone resist.

In some embodiments, the resist film includes an Extreme Ultraviolet (EUV)-sensitive film. In other embodiments, the resist film includes organotin acetylide oxide, tin acetylide oxide, tin acetylide telluride, organotin oxalate, tin oxalate, organotin formates, tin formates, organotin peroxides, or tin peroxides.

In some embodiments, providing the resist film can include depositing a modified precursor on the surface of the substrate to provide the resist film. In particular embodiments, the modified precursor is formed by reacting an organometallic precursor (e.g., any described herein) with an organic co-reactant (e.g., any described herein). In other embodiments, the precursor includes an organometallic compound having one or more ligands, wherein the organic co-reactant replaces at least one of the ligand(s) to provide a modified precursor. In some embodiments, the modified precursor is characterized by an increase in EUV absorption or an increase in an EUV absorption cross-section, as compared to the organometallic precursor. In other embodiments, the modified precursor includes an increased or a decreased carbon content, as compared to the organometallic precursor.

In some embodiments, a dose-to-clear or a dose-to-gel of the incubated film is lower than that of the exposed film. In other embodiments, said patterning includes a radiation dose of about 1-50 mJ/cm², 1-40 mJ/cm², 1-30 mJ/cm², 1-20 mJ/cm², or 1-10 mJ/cm².

In some embodiments, the organometallic precursor includes at least one ligand, and wherein the organic co-reactant replaces the at least one ligand to provide the modified precursor. In other embodiments, the modified precursor is deposited in vapor form.

In other embodiments, the method further includes providing a molar ratio of the organometallic precursor to the organic co-reactant of about 1000:1 to about 1:4. In particular embodiments, such providing can include delivering the organometallic precursor in vapor form and the organic co-reactant in vapor form to a chamber including the semiconductor substrate.

In some embodiments, said patterning includes an EUV exposure having a wavelength in the range of about 10 nm to about 20 nm in a vacuum ambient.

In some embodiments, said patterning further includes a release of carbon dioxide and/or carbon monoxide from the exposed film. In other embodiments, said patterning further includes photopolymerization occurring within the exposed film. In particular embodiments, the organic co-reactant and/or the film includes a photopolymerizable moiety. In further embodiments, the photopolymerizable moiety includes optionally substituted alkenylene, optionally substituted alkynylene, or optionally substituted epoxy (e.g., optionally substituted oxiranyl). In yet other embodiments, the organic co-reactant and/or the film includes alkynyl moieties, carbonyl moieties, dicarbonyl moieties, or haloalkyl moieties.

In some embodiments, said incubating includes a temperature of about 100-200° C. in an ambient atmosphere for an optional time period of about 30-300 seconds. In particular embodiments, said incubating includes a temperature of about of about 100-180° C., 100-250° C., 120-200° C., 120-250° C., or 120-280° C.

In other embodiments, said incubating includes a temperature of about 20-30° C. for a time period of about 1-7 days. In particular embodiments, said incubating can include an inert atmosphere or an ambient atmosphere with an optional degree of humidity (e.g., room humidity (RH), 10% RH, 90 RH %, and ranges therein).

In yet other embodiments, said incubating includes a temperature of about 100-300° C. in an inert atmosphere with an optional degree of humidity for an optional time period of about 1-300 seconds. In some embodiments, said incubating includes a temperature of about of about 150-300° C., 180-300° C., 100-250° C., or 150-250° C. In particular embodiments, said incubating can include an inert atmosphere or an ambient atmosphere with an optional degree of humidity (e.g., room humidity (RH), 10% RH, 90 RH %, and ranges therein).

In some embodiments, said developing includes removing the radiation exposed areas to provide a pattern within a positive tone resist film. In other embodiments, said developing includes removing the radiation unexposed areas to provide a pattern within a negative tone resist.

In some embodiments, said developing includes wet development or dry development. Non-limiting wet development can include water, an acid, a base, a ketone, an ester, an alcohol, an ether, or a combination thereof for an optional time period of about 15-60 seconds. In further embodiments, the wet development further includes one or more surfactants. In other embodiments, the dry development includes gaseous water, oxygen (O₂), a gaseous acid, a gaseous halide, or a combination thereof for an optional time period of about 30-720 seconds at an optional pressure of about 0.1-1 Torr.

In other embodiments, said incubating includes a temperature of about 100-250° C. in an ambient atmosphere, and said developing includes water in liquid or vapor form.

In yet other embodiments, said incubating includes a temperature of about 20-30° C. for a time period of about 1-7 days, and said developing includes a ketone or liquid water in conjunction with a dry development process including water, oxygen (O₂), a gaseous acid, a gaseous halide, or a combination thereof.

In a second aspect, the present disclosure features an apparatus for forming a resist film, the apparatus including: a deposition module, a patterning module, an incubation module, a development modules, and a controller including one or more memory devices, one or more processors, and system control software coded with instructions including machine-readable instructions.

In some embodiments, the deposition module includes a chamber for depositing a resist film (e.g., a patterning radiation-sensitive film, such as an EUV-sensitive film), in which the chamber can be configured to house a semiconductor substrate. In other embodiments, the patterning module includes a photolithography tool with a source of sub-300 nm wavelength radiation (e.g., in which the source can be a source of sub-30 nm wavelength radiation). In yet other embodiments, the incubation module including a chamber for incubating the resist film, in which the chamber can be configured to control one or more incubation conditions (e.g., any herein, such as temperature, atmosphere content, humidity, and/or time period). In some embodiments, the development module includes a chamber for developing the resist film.

In further embodiments, the instructions include machine-readable instructions for (e.g., in the deposition module) causing deposition of an organometallic precursor in presence of an organic co-reactant on a top surface of a semiconductor substrate to form the resist film. In some embodiments, such deposition can form a resist film including organotin acetylide oxide, tin acetylide oxide, tin acetylide telluride, organotin oxalate, tin oxalate, organotin formates, tin formates, organotin peroxides, or tin peroxides. In other embodiments, such deposition can form the patterning radiation-sensitive film as a resist film, in which an organometallic precursor is provided in the presence of an organic co-reactant. In other embodiments, such deposition can include causing a change of a molar ratio of the organometallic precursor and the organic co-reactant to form the patterning radiation-sensitive film.

In some embodiments, causing deposition can include depositing a modified precursor on the top surface of the semiconductor substrate to form the resist film, wherein the organometallic precursor is provided the presence of the organic co-reactant to provide the modified precursor.

In some embodiments, the instructions include machine-readable instructions for (e.g., in the patterning module) causing patterning of the resist film with sub-300 nm resolution (e.g., or with sub-30 nm resolution) directly by patterning radiation exposure (e.g., by EUV exposure), thereby forming an exposed film having radiation exposed areas and radiation unexposed areas. In other embodiments, the exposed film has EUV exposed areas and EUV unexposed areas. In some embodiments, such patterning includes a radiation dose of about 1-50 mJ/cm², 1-40 mJ/cm², 1-30 mJ/cm², 1-20 mJ/cm², or 1-10 mJ/cm².

In some embodiments, the instructions include (e.g., in the incubation module) causing incubation of the exposed film at a temperature of about 20-300° C., thereby providing an incubated film. In other embodiments, such incubation can include a temperature of about 100-250° C. in an ambient atmosphere for an optional time period of about 30-300 seconds; a temperature of about 20-30° C. for a time period of about 1-7 days; or a temperature of about 150-300° C. in an inert atmosphere with an optional degree of humidity for an optional time period of about 1-300 seconds.

In yet other embodiments, the instructions include machine-readable instructions for (e.g., in the development module) causing development of the incubated film to remove the radiation exposed areas or the radiation unexposed areas to provide a pattern within the resist film. In particular embodiments, the machine-readable instructions include instructions for causing removal of the EUV exposed areas or the EUV unexposed areas. In some embodiments, such development can include delivering one or more of the following into the development module: water, an acid, a base, a ketone, an ester, an alcohol, an ether, a surfactant, or a combination thereof. In other embodiments, such development can include delivering one or more of the following into the development module: gaseous water, oxygen (O₂), a gaseous acid, a gaseous halide, or a combination thereof.

In any embodiment herein, the patterning radiation-sensitive film includes an extreme ultraviolet (EUV)-sensitive film, a deep-ultraviolet (DUV)-sensitive film, a photoresist film, or a photopatternable film.

In any embodiment herein, the patterning radiation-sensitive film includes a plurality of polymerizable moieties (e.g., photopolymerizable moieties), alkenylene moieties, alkynylene moieties, carbonyl moieties, or dicarbonyl moieties.

In any embodiment herein, the patterning radiation-sensitive film includes an organometallic material or an organometal oxide material.

In any embodiment herein, the organometallic precursor includes a structure having formula (I), (Ia), (III), (IV), (V), (VI), (VII), or (VIII), as described herein.

In any embodiment herein, the organometallic precursor includes a structure having formula (I):

MₐR_{b}L_{c} (I),
wherein: M is a metal or a metalloid (e.g., any herein); each R is, independently, halo, optionally substituted alkyl, optionally substituted aryl, optionally substituted amino, optionally substituted alkoxy, or L; each L is, independently, is a ligand, ion, or other moiety that is reactive with the organic co-reactant or a counter-reactant, in which R and L with M, taken together, can optionally form a heterocyclyl group or in which R and L, taken together, can optionally form a heterocyclyl group; a≥1 (e.g., a is 1, 2, or 3); b≥1 (e.g., b is 1, 2, 3, 4, 5, or 6); and c≥1 (e.g., c is 1, 2, 3, 4, 5, 6).

In some embodiments, each R is L and/or M is tin (Sn), such as Sn(IV) or Sn(II). In other embodiments, each L is, independently, H, halo, optionally substituted alkyl, optionally substituted aryl, optionally substituted amino, optionally substituted bis(trialkylsilyl)amino, optionally substituted trialkylsilyl, or optionally substituted alkoxy (e.g., any L described herein).

In any embodiment herein, the organic co-reactant includes a structure having formula (II), (IIa), (IIb), (IIc), (IId), or (IIe), as described herein.

In any embodiment herein, the organic co-reactant includes one or more polymerizable moieties, alkynyl moieties, carbonyl moieties, dicarbonyl moieties, or haloalkyl moieties. In some embodiments, the organic co-reactant includes a structure having formula (II):

X¹—Z—X² (II),
wherein: each of X¹ and X² is, independently, a leaving group (e.g., halo, H, hydroxyl, optionally substituted alkyl, optionally substituted alkoxy, or optionally substituted aryl); and Z is carbonyl, dicarbonyl, optionally substituted alkylene, optionally substituted haloalkylene, optionally substituted alkenylene, or optionally substituted alkynylene.

In any embodiment herein, the organic co-reactant has a vapor pressure of from about 0.1 mTorr to about 100 mTorr (e.g., 0.1 mTorr to 50 mTorr or 0.5 mTorr to 100 mTorr).

In any embodiment herein, the organometallic precursor includes an organometallic compound having one or more ligands (e.g., at least one ligand). In further embodiments, the organic co-reactant replaces at least some significant, detectable percentage of one ligand to provide the modified precursor. In other embodiments, the organic co-reactant replaces at least one of the ligand(s) of the organometallic precursor to provide the modified precursor. In some embodiments, the detectable percentage is from about at least 0.1%, 0.5%, 1%, or 3%, as well as from 0.1% to 5%.

In any embodiment herein, a single organometallic precursor is employed with one or more organic co-reactants. In other embodiments, two, three, four, or more different organometallic precursors are employed within one or more organic co-reactants.

In any embodiment herein, a single organometallic precursor is employed with a single organic co-reactant. In other embodiments, a single organometallic precursor is employed with two, three, four, or more different organic co-reactants. In yet other embodiments, two or more different organometallic precursors are employed with a single organic co-reactant. In other embodiments, two or more different organometallic precursors are employed with two or more different organic co-reactants.

In any embodiment herein, a molar ratio of the organometallic precursor to the organic co-reactant of from about 1000:1 to about 1:4 (e.g., about 1000:1 to 1:4, 100:1 to 10:1, 50:1 to 1:4, etc.).

In any embodiment herein, depositing includes depositing the modified precursor in vapor form. In other embodiments, said depositing includes providing an organometallic precursor, an organic co-reactant, and/or a counter-reactant in vapor form. Non-limiting deposition processes include chemical vapor deposition (CVD), as well as atomic layer deposition (ALD), molecular layer deposition (MLD), and plasma-enhanced forms thereof.

In any embodiment herein, the modified precursor includes the use of a chalcogenide precursor or an oxygen-containing counter-reactant.

In any embodiment herein, said providing or said depositing further includes providing a counter-reactant. Non-limiting counter-reactants include oxygen or a chalcogenide precursor, as well as any described herein (e.g., an oxygen-containing counter-reactant, including oxygen (O₂), ozone (O₃), water, a peroxide, hydrogen peroxide, oxygen plasma, water plasma, an alcohol, a dihydroxy alcohol, a polyhydroxy alcohol, a fluorinated dihydroxy alcohol, a fluorinated polyhydroxy alcohol, a fluorinated glycol, formic acid, and other sources of hydroxyl moieties, as well as combinations thereof). Additional details follow.

### Definitions

By “alkenyl” is meant an optionally substituted C₂₋₂₄ alkyl group having one or more double bonds. The alkenyl group can be cyclic (e.g., C₃₋₂₄ cycloalkenyl) or acyclic. The alkenyl group can also be substituted or unsubstituted. For example, the alkenyl group can be substituted with one or more substitution groups, as described herein for alkyl.

By “alkenylene” is meant a multivalent (e.g., bivalent) form of an alkenyl group, which is an optionally substituted C₂₋₂₄ alkyl group having one or more double bonds. The alkenylene group can be cyclic (e.g., C₃₋₂₄ cycloalkenyl) or acyclic. The alkenylene group can be substituted or unsubstituted. For example, the alkenylene group can be substituted with one or more substitution groups, as described herein for alkyl. Exemplary, non-limiting alkenylene groups include —CH═CH— or —CH═CHCH₂—.

By “alkoxy” is meant —OR, where R is an optionally substituted alkyl group, as described herein. Exemplary alkoxy groups include methoxy, ethoxy, butoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” and the prefix “alk” is meant a branched or unbranched saturated hydrocarbon group of 1 to 24 carbon atoms, such as methyl (Me), ethyl (Et), n-propyl (n-Pr), isopropyl (i-Pr), cyclopropyl, n-butyl (n-Bu), isobutyl (i-Bu), s-butyl (s-Bu), t-butyl (t-Bu), cyclobutyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic (e.g., C₃₋₂₄ cycloalkyl) or acyclic. The alkyl group can be branched or unbranched. The alkyl group can also be substituted or unsubstituted. For example, the alkyl group can include haloalkyl, in which the alkyl group is substituted by one or more halo groups, as described herein. In another example, the alkyl group can be substituted with one, two, three or, in the case of alkyl groups of two carbons or more, four substituents independently selected from the group consisting of: (1) C₁₋₆ alkoxy (e.g., —O-Ak, wherein Ak is optionally substituted C₁₋₆ alkyl); (2) amino (e.g., —NR^{N1}R^{N2}, where each of R^{N1} and R^{N2} is, independently, H or optionally substituted alkyl, or R^{N1} and R^{N2}, taken together with the nitrogen atom to which each are attached, form a heterocyclyl group); (3) aryl; (4) arylalkoxy (e.g., —O-Lk-Ar, wherein Lk is a bivalent form of optionally substituted alkyl and Ar is optionally substituted aryl); (5) aryloyl (e.g., —C(O)—Ar, wherein Ar is optionally substituted aryl); (6) cyano (e.g., —CN); (7) carboxyaldehyde (e.g., —C(O)H); (8) carboxyl (e.g., —CO₂H); (9) C₃₋₈ cycloalkyl (e.g., a monovalent saturated or unsaturated non-aromatic cyclic C₃₋₈ hydrocarbon group); (10) halo (e.g., F, Cl, Br, or I); (11) heterocyclyl (e.g., a 5-, 6- or 7-membered ring, unless otherwise specified, containing one, two, three, or four non-carbon heteroatoms, such as nitrogen, oxygen, phosphorous, sulfur, or halo); (12) heterocyclyloxy (e.g., —O-Het, wherein Het is heterocyclyl, as described herein); (13) heterocyclyloyl (e.g., —C(O)—Het, wherein Het is heterocyclyl, as described herein); (14) hydroxyl (e.g., —OH); (15)N-protected amino; (16) nitro (e.g., —NO₂); (17) oxo (e.g., ═O); (18) —CO₂R^{A}, where R^{A} is selected from the group consisting of (a) C₁₋₆ alkyl, (b) C₄₋₁₈ aryl, and (c) (C₄₋₁₈ aryl) C₁₋₆ alkyl (e.g., -Lk-Ar, wherein Lk is a bivalent form of optionally substituted alkyl group and Ar is optionally substituted aryl); (19) —C(O)NR^{B}R^{C}, where each of R^{B} and R^{C} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -Lk-Ar, wherein Lk is a bivalent form of optionally substituted alkyl group and Ar is optionally substituted aryl); and (20) —NR^{G}R^{H}, where each of R^{G} and R^{H} is, independently, selected from the group consisting of (a) hydrogen, (b) an N-protecting group, (c) C₁₋₆ alkyl, (d) C₂₋₆ alkenyl (e.g., optionally substituted alkyl having one or more double bonds), (e) C₂₋₆ alkynyl (e.g., optionally substituted alkyl having one or more triple bonds), (f) C₄₋₁₈ aryl, (g) (C₄₋₁₈ aryl) C₁₋₆ alkyl (e.g., Lk-Ar, wherein Lk is a bivalent form of optionally substituted alkyl group and Ar is optionally substituted aryl), (h) C₃₋₈ cycloalkyl, and (i) (C₃₋₈ cycloalkyl) C₁₋₆ alkyl (e.g., -Lk-Cy, wherein Lk is a bivalent form of optionally substituted alkyl group and Cy is optionally substituted cycloalkyl, as described herein), wherein in one embodiment no two groups are bound to the nitrogen atom through a carbonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene” is meant a multivalent (e.g., bivalent) form of an alkyl group, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. The alkylene group can be branched or unbranched. The alkylene group can also be substituted or unsubstituted. For example, the alkylene group can be substituted with one or more substitution groups, as described herein for alkyl.

By “alkynyl” is meant an optionally substituted C₂₋₂₄ alkyl group having one or more triple bonds. The alkynyl group can be cyclic or acyclic and is exemplified by ethynyl, 1-propynyl, and the like. The alkynyl group can also be substituted or unsubstituted. For example, the alkynyl group can be substituted with one or more substitution groups, as described herein for alkyl.

By “alkynylene” is meant a multivalent (e.g., bivalent) form of an alkynyl group, which is an optionally substituted C₂₋₂₄ alkyl group having one or more triple bonds. The alkynylene group can be cyclic or acyclic. The alkynylene group can be substituted or unsubstituted. For example, the alkynylene group can be substituted with one or more substitution groups, as described herein for alkyl. Exemplary, non-limiting alkynylene groups include —C≡C— or —C≡CCH₂—.

By “amino” is meant —NR^{N1}R^{N2}, where each of R^{N1} and R^{N2} is, independently, H, optionally substituted alkyl, or optionally substituted aryl, or R^{N1} and R^{N2}, taken together with the nitrogen atom to which each are attached, form a heterocyclyl group, as defined herein.

By “aminoalkyl” is meant an alkyl group, as defined herein, substituted by an amino group, as defined herein.

By “aminoaryl” is meant an aryl group, as defined herein, substituted by an amino group, as defined herein.

By “aryl” is meant a group that contains any carbon-based aromatic group including, but not limited to, phenyl, benzyl, anthracenyl, anthryl, benzocyclobutenyl, benzocyclooctenyl, biphenylyl, chrysenyl, dihydroindenyl, fluoranthenyl, indacenyl, indenyl, naphthyl, phenanthryl, phenoxybenzyl, picenyl, pyrenyl, terphenyl, and the like, including fused benzo-C₄₋₈ cycloalkyl radicals (e.g., as defined herein) such as, for instance, indanyl, tetrahydronaphthyl, fluorenyl, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents, such as any described herein for alkyl.

By “carbonyl” is meant a —C(O)— group, which can also be represented as >C═O.

By “cycloalkyl” is meant a monovalent saturated or unsaturated non-aromatic or aromatic cyclic hydrocarbon group of from three to eight carbons, unless otherwise specified, and is exemplified by cyclopropyl, cyclobutyl, cyclopentyl, cyclopentadienyl, cyclohexyl, cycloheptyl, bicyclo[2.2.1.]heptyl, and the like. The cycloalkyl group can also be substituted or unsubstituted. For example, the cycloalkyl group can be substituted with one or more groups including those described herein for alkyl.

By “dicarbonyl” is meant any moiety or compound including two carbonyl groups, as defined herein. Non-limiting dicarbonyl moieties include 1,2-dicarbonyl (e.g., R^{C1}—C(O)—C(O)R^{C2}, in which each of R^{C1} and R^{C2} is, independently, optionally substituted alkyl, halo, optionally substituted alkoxy, hydroxyl, or a leaving group); 1,3-dicarbonyl (e.g., R^{C1}—C(O)—C(R^{1a}R^{2a})—C(O)R^{C2}, in which each of R^{C1} and R^{C2} is, independently, optionally substituted alkyl, halo, optionally substituted alkoxy, hydroxyl, or a leaving group and in which each of R^{1a} and R^{2a} is, independently, H or an optional substituent provided for alkyl, as defined herein); and 1,4-dicarbonyl (e.g., R^{C1}—C(O)—C(R^{1a}R^{2a})—C(R^{3a}R^{4a})—C(O)R^{C2}, in which each of R^{C1} and R^{C2} is, independently, optionally substituted alkyl, halo, optionally substituted alkoxy, hydroxyl, or a leaving group and in which each of R^{1a}, R^{2a}, R^{3a}, and R^{4a} is, independently, H or an optional substituent provided for alkyl, as defined herein). A non-limiting dicarbonyl moiety includes, e.g., —C(O)—C(O).

By “halo” is meant F, Cl, Br, or I.

By “haloalkyl” is meant an alkyl group, as defined herein, substituted with one or more halo.

By “haloalkylene” is meant an alkylene group, as defined herein, substituted with one or more halo.

By “heterocyclyl” is meant a 3-, 4-, 5-, 6- or 7-membered ring (e.g., a 5-, 6- or 7 -membered ring), unless otherwise specified, containing one, two, three, or four non-carbon heteroatoms (e.g., independently selected from the group consisting of nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include acridinyl, adenyl, alloxazinyl, azaadamantanyl, azabenzimidazolyl, azabicyclononyl, azacycloheptyl, azacyclooctyl, azacyclononyl, azahypoxanthinyl, azaindazolyl, azaindolyl, azecinyl, azepanyl, azepinyl, azetidinyl, azetyl, aziridinyl, azirinyl, azocanyl, azocinyl, azonanyl, benzimidazolyl, benzisothiazolyl, benzisoxazolyl, benzodiazepinyl, benzodiazocinyl, benzodihydrofuryl, benzodioxepinyl, benzodioxinyl, benzodioxanyl, benzodioxocinyl, benzodioxolyl, benzodithiepinyl, benzodithiinyl, benzodioxocinyl, benzofuranyl, benzophenazinyl, benzopyranonyl, benzopyranyl, benzopyrenyl, benzopyronyl, benzoquinolinyl, benzoquinolizinyl, benzothiadiazepinyl, benzothiadiazolyl, benzothiazepinyl, benzothiazocinyl, benzothiazolyl, benzothienyl, benzothiophenyl, benzothiazinonyl, benzothiazinyl, benzothiopyranyl, benzothiopyronyl, benzotriazepinyl, benzotriazinonyl, benzotriazinyl, benzotriazolyl, benzoxathiinyl, benzotrioxepinyl, benzoxadiazepinyl, benzoxathiazepinyl, benzoxathiepinyl, benzoxathiocinyl, benzoxazepinyl, benzoxazinyl, benzoxazocinyl, benzoxazolinonyl, benzoxazolinyl, benzoxazolyl, benzylsultamyl benzylsultimyl, bipyrazinyl, bipyridinyl, carbazolyl (e.g., 4H-carbazolyl), carbolinyl (e.g., O-carbolinyl), chromanonyl, chromanyl, chromenyl, cinnolinyl, coumarinyl, cytdinyl, cytosinyl, decahydroisoquinolinyl, decahydroquinolinyl, diazabicyclooctyl, diazetyl, diaziridinethionyl, diaziridinonyl, diaziridinyl, diazirinyl, dibenzisoquinolinyl, dibenzoacridinyl, dibenzocarbazolyl, dibenzofuranyl, dibenzophenazinyl, dibenzopyranonyl, dibenzopyronyl (xanthonyl), dibenzoquinoxalinyl, dibenzothiazepinyl, dibenzothiepinyl, dibenzothiophenyl, dibenzoxepinyl, dihydroazepinyl, dihydroazetyl, dihydrofuranyl, dihydrofuryl, dihydroisoquinolinyl, dihydropyranyl, dihydropyridinyl, dihydroypyridyl, dihydroquinolinyl, dihydrothienyl, dihydroindolyl, dioxanyl, dioxazinyl, dioxindolyl, dioxiranyl, dioxenyl, dioxinyl, dioxobenzofuranyl, dioxolyl, dioxotetrahydrofuranyl, dioxothiomorpholinyl, dithianyl, dithiazolyl, dithienyl, dithiinyl, furanyl, furazanyl, furoyl, furyl, guaninyl, homopiperazinyl, homopiperidinyl, hypoxanthinyl, hydantoinyl, imidazolidinyl, imidazolinyl, imidazolyl, indazolyl (e.g., 1H-indazolyl), indolenyl, indolinyl, indolizinyl, indolyl (e.g., 1H-indolyl or 3H-indolyl), isatinyl, isatyl, isobenzofuranyl, isochromanyl, isochromenyl, isoindazoyl, isoindolinyl, isoindolyl, isopyrazolonyl, isopyrazolyl, isoxazolidiniyl, isoxazolyl, isoquinolinyl, isoquinolinyl, isothiazolidinyl, isothiazolyl, morpholinyl, naphthindazolyl, naphthindolyl, naphthiridinyl, naphthopyranyl, naphthothiazolyl, naphthothioxolyl, naphthotriazolyl, naphthoxindolyl, naphthyridinyl, octahydroisoquinolinyl, oxabicycloheptyl, oxauracil, oxadiazolyl, oxazinyl, oxaziridinyl, oxazolidinyl, oxazolidonyl, oxazolinyl, oxazolonyl, oxazolyl, oxepanyl, oxetanonyl, oxetanyl, oxetyl, oxtenayl, oxindolyl, oxiranyl, oxobenzoisothiazolyl, oxochromenyl, oxoisoquinolinyl, oxoquinolinyl, oxothiolanyl, phenanthridinyl, phenanthrolinyl, phenazinyl, phenothiazinyl, phenothienyl (benzothiofuranyl), phenoxathiinyl, phenoxazinyl, phthalazinyl, phthalazonyl, phthalidyl, phthalimidinyl, piperazinyl, piperidinyl, piperidonyl (e.g., 4-piperidonyl), pteridinyl, purinyl, pyranyl, pyrazinyl, pyrazolidinyl, pyrazolinyl, pyrazolopyrimidinyl, pyrazolyl, pyridazinyl, pyridinyl, pyridopyrazinyl, pyridopyrimidinyl, pyridyl, pyrimidinyl, pyrimidyl, pyronyl, pyrrolidinyl, pyrrolidonyl (e.g., 2-pyrrolidonyl), pyrrolinyl, pyrrolizidinyl, pyrrolyl (e.g., 2H-pyrrolyl), pyrylium, quinazolinyl, quinolinyl, quinolizinyl (e.g., 4H-quinolizinyl), quinoxalinyl, quinuclidinyl, selenazinyl, selenazolyl, selenophenyl, succinimidyl, sulfolanyl, tetrahydrofuranyl, tetrahydrofuryl, tetrahydroisoquinolinyl, tetrahydroisoquinolyl, tetrahydropyridinyl, tetrahydropyridyl (piperidyl), tetrahydropyranyl, tetrahydropyronyl, tetrahydroquinolinyl, tetrahydroquinolyl, tetrahydrothienyl, tetrahydrothiophenyl, tetrazinyl, tetrazolyl, thiadiazinyl (e.g., 6H-1,2,5-thiadiazinyl or 2H,6H-1,5,2-dithiazinyl), thiadiazolyl, thianthrenyl, thianyl, thianaphthenyl, thiazepinyl, thiazinyl, thiazolidinedionyl, thiazolidinyl, thiazolyl, thienyl, thiepanyl, thiepinyl, thietanyl, thietyl, thiiranyl, thiocanyl, thiochromanonyl, thiochromanyl, thiochromenyl, thiodiazinyl, thiodiazolyl, thioindoxyl, thiomorpholinyl, thiophenyl, thiopyranyl, thiopyronyl, thiotriazolyl, thiourazolyl, thioxanyl, thioxolyl, thymidinyl, thyminyl, triazinyl, triazolyl, trithianyl, urazinyl, urazolyl, uretidinyl, uretinyl, uricyl, uridinyl, xanthenyl, xanthinyl, xanthionyl, and the like, as well as modified forms thereof (e.g., including one or more oxo and/or amino) and salts thereof. The heterocyclyl group can be substituted or unsubstituted. For example, the heterocyclyl group can be substituted with one or more substitution groups, as described herein for aryl.

By “hydroxyl” is meant —OH.

By “imino” is meant —NR—, in which R can be H or optionally substituted alkyl.

By “oxo” is meant an ═O group.

By “oxy” is meant —O—.

As used herein, the term “about” means+/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

Other features and advantages of the invention will be apparent from the following description and the claims.

### BRIEF DESCRIPTION OF THE DRAWINGS

FIG. 1A-1E presents non-limiting methods that employ an organometallic precursor and an organic co-reactant. Provided are (A) a first method 100 to provide either a positive tone resist (path i) or a negative tone resist (path ii); (B) a block diagram of an illustrative method 150; (C) a graph showing the effect of non-limiting post-exposure incubation conditions (at 100° C., 150° C., or 175° C. for two minutes) with water as the developer; (D) a graph showing the effect of non-limiting post-exposure incubation conditions (at 100° C., 150° C., or 200° C. for two minutes; or at 150° C. for two minutes with a delay of four days to begin development) with 2-heptanone as the developer; and (E) a graph showing the effect of non-limiting post-exposure incubation conditions (at 150° C. for two minutes) with water alone, isopropyl alcohol (IPA) alone, or a 1:1 mixture of water and IPA.

FIG. 2A-2H presents schematic diagrams of illustrative organometallic precursors and organic co-reactants to deposit a modified precursor. Provided are an Sn(IV) organometallic precursor (I-1) in the presence of (A) a first organic co-reactant (C-1) or (B) a second organic co-reactant (C-2); a different Sn(IV) organometallic precursor (I-2) in the presence of (C) a first organic co-reactant (C-1) or (D) a second organic co-reactant (C-2); (E) an Sn(II) organometallic precursor (I-3) in the presence of a first organic co-reactant (C-1); (F) an Sn(II) organometallic precursor (I-3) in the presence of a first organic co-reactant (C-1) and a tellurium-containing precursor (TeR₂); (G) another Sn(II) organometallic precursor (I-4) in the presence of a second organic co-reactant (C-2); and (H) an Sn(II) organometallic precursor (I-4) in the presence of a third organic co-reactant (C-3).

FIG. 3A-3B shows non-limiting scanning electron microscopy (SEM) images of resist films at half pitch (HP) 14 nm (HP 14). Provided are resist films that were deposited using (A) a first tin-containing precursor including a methyl group, a second tin-containing precursor including an isopropyl group, and acetone as the organic co-reactant; and (B) a first tin-containing precursor including a methyl group and acetone as the organic co-reactant. EUV patterning was conducted at PSI in Switzerland.

FIG. 4A-4C presents schematic diagrams of illustrative stacks. Provided are (A) a stack including a film 402 deposited with a modified precursor; (B) another stack including a film 412 having differing carbon content in regions 412a, 412b by controlling the amount of the organometallic precursor and organic co-reactant; and (C) yet another stack including a film 423 deposited with a modified precursor, in which the film 423 is a capping layer disposed above a photoresist layer 422.

FIG. 5 presents a schematic illustration of an embodiment of a process station 500 for dry development.

FIG. 6 presents a schematic illustration of an embodiment of a multi-station processing tool 600.

FIG. 7 presents a schematic illustration of an embodiment of an inductively coupled plasma apparatus 700.

FIG. 8 presents a schematic illustration of an embodiment of a semiconductor process cluster tool architecture 800.

### DETAILED DESCRIPTION

This disclosure relates generally to the field of semiconductor processing. In particular, the disclosure is directed to the use of one or more organometallic precursors in combination with one or more organic co-reactants, thereby providing modified precursors for deposition. Such modified precursors can include the metal centers of the organometallic precursor and the organic moieties of the organic co-reactant. In this way, the chemical, physical, and/or optical properties of the deposited film can be controlled by controlling the extent of reaction between the organometallic precursor and the organic co-reactant, by selecting the appropriate combination of moieties and ligand present in the precursor and co-reactant, and/or by determining the desired amount of precursor and co-reactant to introduce during deposition. Further expansion of the film's properties can be obtained by incubating the film after exposure. As described herein, such modified precursors can provide films that can be incubated and developed to further enhanced material differences between the exposed and unexposed regions.

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

EUV lithography makes use of EUV resists that are patterned to form masks for use in etching underlying layers. EUV resists may be polymer-based chemically amplified resists (CARs) produced by liquid-based spin-on techniques. An alternative to CARs is directly photopatternable metal oxide-containing films, such as those available from Inpria Corp. (Corvallis, OR), and described, for example, in U.S. Pat Pub. Nos. US 2017/0102612, US 2016/0216606, and US 2016/0116839, incorporated by reference herein at least for their disclosure of photopatternable metal oxide-containing films. Such films may be produced by spin-on techniques or dry vapor-deposited. The metal oxide-containing film can be patterned directly (i.e., without the use of a separate photoresist) by EUV exposure in a vacuum ambient providing sub-30 nm patterning resolution, for example as described in U.S. Pat. No. 9,996,004, issued Jun. 12, 2018 and titled EUV PHOTOPATTERNING OF VAPOR-DEPOSITED METAL OXIDE-CONTAINING HARDMASKS, and/or in International Appl. No. PCT/US19/31618, published as International Pub. No. WO 2019/217749, filed May 9, 2019, and titled METHODS FOR MAKING EUV PATTERNABLE HARD MASKS, the disclosures of which at least relating to the composition, deposition, and patterning of directly photopatternable metal oxide films to form EUV resist masks is incorporated by reference herein. Generally, the patterning involves exposure of the EUV resist with EUV radiation to form a photo pattern in the resist, followed by development to remove a portion of the resist according to the photo pattern to form the mask.

Directly photopatternable EUV or DUV resists may be composed of or contain metals and/or metal oxides mixed within organic components. The metals/metal oxides can enhance the EUV or DUV photon adsorption, generate secondary electrons, and/or show increased etch selectivity to an underlying film stack and device layers. These resists can be developed using a wet (solvent) approach, which requires the wafer to move to the track, where it is exposed to developing solvent, dried, and then baked. Such resists may be also be developed using a dry approach or a combination of wet and dry approaches, as described herein.

Generally, resists can be employed as a positive tone resist or a negative tone resist by controlling the chemistry of the resist and/or the solubility or reactivity of the developer. It would be beneficial to have a EUV or DUV resist that can serve as either a negative tone resist or a positive tone resist.

It would also be beneficial to have a resist in which post-exposure incubation and developing conditions can tune the DtG or DtC or DtS characteristics of the film. In particular embodiments, DtC is considered to be an exposure dose that results in removal of the exposed photoresist area upon being developed (e.g., as in a positive tone resist). Such removal can be quantified in any useful manner, such as a change in thickness (e.g., a certain decrease in thickness) of the exposed area. In other embodiments, DtG is considered to be an exposure dose that results in insolubility of the exposed photoresist area upon being developed (e.g., as in a negative tone resist). Such insolubility can be quantified in any useful manner, such as a change in thickness (e.g., a certain increase in thickness) of the exposed area. In yet other embodiments, DtS is considered to be an exposure dose that results in producing a particular dimension in the exposed photoresist area upon being developed.

The present disclosure generally includes any useful method that employs a film formed from a modified precursor, in which the film is further incubated to provide enhanced material differences between the exposed and unexposed regions and then developed to removed either the exposed or unexposed regions. Such methods can include any useful lithography processes, deposition processes, radiation exposure processes, development processes, and post-application processes, as described herein. In some embodiments, the choice of the organic co-reactant can provide either a positive tone resist or a negative tone resist. Accordingly, the method herein also includes those that employ a positive tone resist or a negative tone resist. Development of a positive or negative tone resist can include wet development, dry development, or combinations thereof.

While the following may describe techniques as relating to EUV processes, such techniques may also be applicable to other next generation lithographic techniques. Various radiation sources may be employed, including EUV (generally about 13.5 nm), DUV (deep-UV, generally in the 248 nm or 193 nm range with excimer laser sources), X-ray (including EUV at the lower energy range of the X-ray range), and e-beam (including a wide energy range).

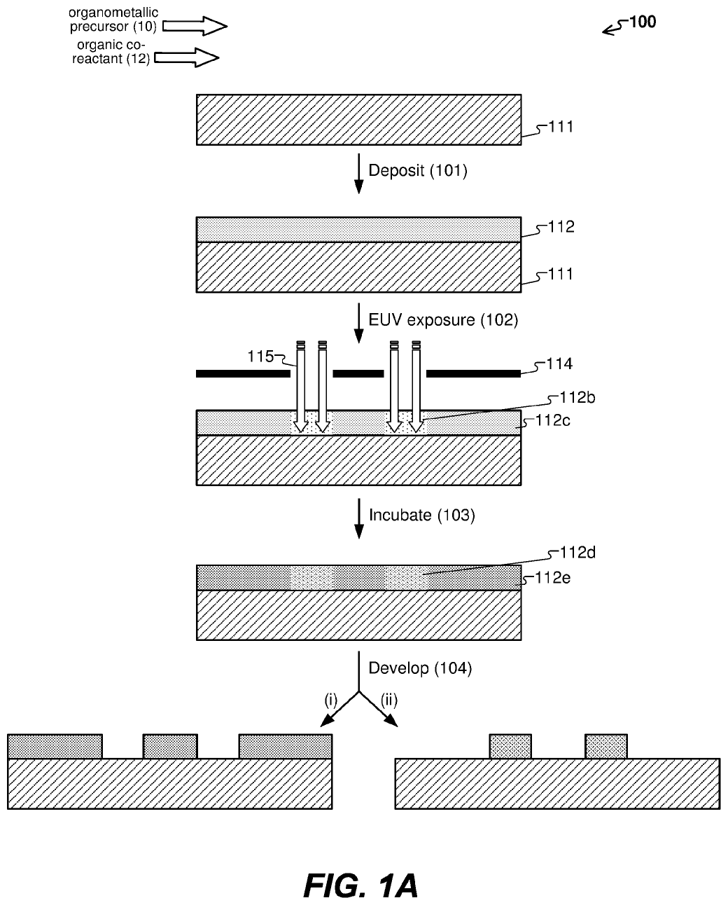

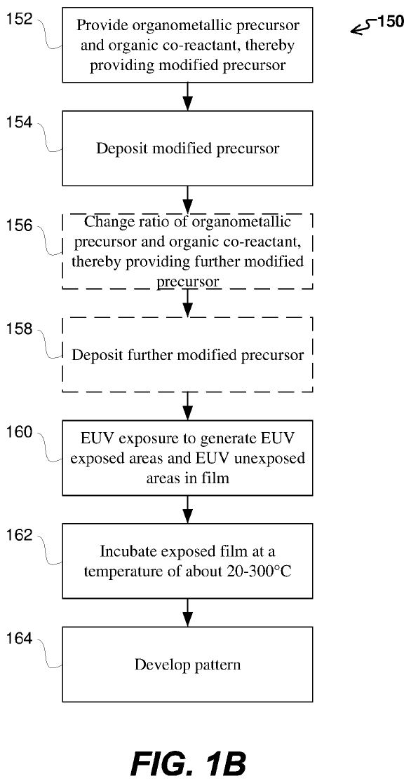

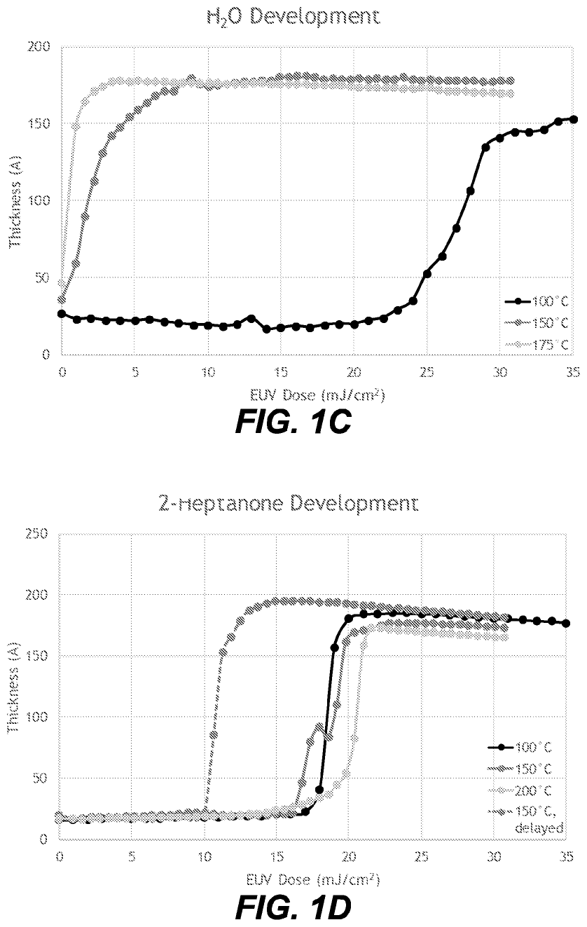

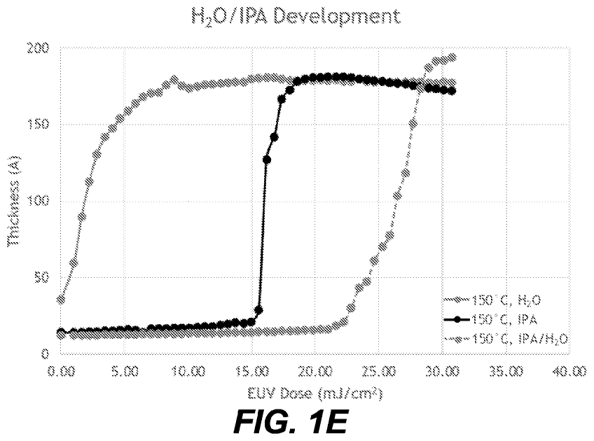

FIG. 1A provides an exemplary method 100 as a schematic, and FIG. 1B provides an exemplary method 150 as a flowchart. Turning to FIG. 1A, an exemplary method 100 can include providing an organometallic precursor 10 in the presence of an organic co-reactant 12 (e.g., any described herein). In particular, the organic co-reactant replaces at least one ligand in the organometallic precursor to provide a modified precursor. The method 100 further includes depositing 101 a modified precursor as a film 112 on a top surface of a substrate 111, wherein the film 112 includes an EUV-sensitive material. Deposition can include use of a counter-reactant, such as any described herein (e.g., water vapor).

The composition of the film is determined by the organometallic precursor, organic co-reactant, and counter-reactant employed during deposition. Non-limiting films can include organotin acetylide oxide (e.g., using an organotin precursor, an acetylene-containing co-reactant, and an optional oxygen-containing counter-reactant); tin acetylide oxide (e.g., using an organotin precursor, an acetylene-containing co-reactant, and an optional oxygen-containing counter-reactant); tin acetylide telluride (e.g., using an organotin precursor, an acetylene-containing co-reactant, and a tellurium-containing counter-reactant); organotin oxalate (e.g., using an organotin precursor, an oxalyl-containing co-reactant, and an optional oxygen-containing counter-reactant); tin oxalate (e.g., using an organotin precursor, an oxalyl-containing co-reactant, and an optional oxygen-containing counter-reactant), organotin formates (e.g., using an organotin precursor, a monocarboxylic acid-containing co-reactant, and an optional oxygen-containing counter-reactant), tin formates (e.g., using an organotin precursor, a monocarboxylic acid-containing co-reactant, and an optional oxygen-containing counter-reactant), organotin peroxides (e.g., using an organotin precursor, a peroxo-containing co-reactant, and an optional oxygen-containing counter-reactant), or tin peroxides (e.g., using an organotin precursor, a peroxo-containing co-reactant, and an optional oxygen-containing counter-reactant).

The method can further include steps to treat the deposited EUV-sensitive film. Such steps, while not required for creating the film, can be useful for using the film as a PR. Accordingly, the method 100 further includes patterning the film by an EUV exposure 102 to provide an exposed film having EUV exposed areas 112b and EUV unexposed areas 112c. Patterning can include use of a mask 114 having EUV transparent regions and EUV opaque regions, in which EUV beams 115 are transmitted through the EUV transparent region and into the film 112. EUV exposure can include, e.g., an exposure having a wavelength in the range of about 10 nm to about 20 nm in a vacuum ambient (e.g., about 13.5 nm in a vacuum ambient). In certain embodiments, the radiation dose is about 1-50 mJ/cm². In other embodiments, the radiation dose is about 1-10 mJ/cm², 1-20 mJ/cm², 1-30 mJ/cm², 1-40 mJ/cm², 10-20 mJ/cm², 10-30 mJ/cm², 10-40 mJ/cm², or 10-50 mJ/cm².

Once a pattern is provided, the method 100 can include incubating 103 the film to further differentiate one or more material properties between the exposed and unexposed regions, thereby providing an incubated film having incubated, exposed regions 112d and incubated, unexposed regions 112e. Without wishing to be limited by mechanism, incubation can promote certain chemical or physical processes within the exposed and unexposed regions to further differentiate solubility of material in those regions upon exposure to a developer. In one non-limiting instance, incubation can result in a low level of crosslinking within the unexposed region and a high level of crosslinking within the exposed region, thereby rendering the exposed region to be resistant to dissolution within the developer. The extent of crosslinking can be affected by the extent of water loss, thermal decomposition of tin-organic moieties, and/or loss of organic ligands in a certain region. Such crosslinking can include the formation of metal-oxygen bonds, metal-carbon bonds, or carbon-carbon bonds (e.g., between ligands).

Incubation conditions can include incubating the exposed film at a temperature of about 20-300° C. In one instance, incubating an exposed film at a temperature of about 100-250° C. in an ambient atmosphere provides increased material differences between the exposed and unexposed areas. This difference can be used to provide enhanced DtG or DtC or DtS when developed with certain developers (e.g., an aqueous developer, gaseous water, or halide vapor). Such incubation for the film can include a time period of about 30-300 seconds.

In another instance, incubating an exposed film at a lower temperature of about 20-30° C. for an extended time period (e.g., for 1-7 days) provides increased material differences between the exposed and unexposed areas. This difference can be used to provide enhanced DtG or DtC or DtS when developed with certain developers (e.g., an aqueous developer, an organic developer, or a combination thereof, as well as any described herein). Such incubation can occur in an ambient atmosphere (e.g., ambient air) or other atmosphere having one or more of the following: nitrogen (N₂), oxygen (O₂), water vapor (H₂O), carbon dioxide (CO₂), carbon monoxide (CO), argon (Ar), helium (He), or combinations thereof.

In particular examples, exposure to an elevated temperature (e.g., more than 200° C., 250° C., or above) can render the entire film to be insoluble, thus losing the patterning resolution provided by radiation exposure. However, elevated temperatures can be employed in controlled atmosphere conditions. Thus, in one instance, incubating an exposed film at an elevated temperature of about 150-300° C. in an inert atmosphere provides increased material differences between the exposed and unexposed areas. This difference can be used to provide enhanced DtG or DtC or DtS when developed with certain developers (e.g., an aqueous developer, an organic developer, or a combination thereof, as well as any described herein). Such incubation can include a time period of about 1-300 seconds. Optionally, some degree of humidity can be present. Such incubation can occur in an atmosphere having one or more of the following: nitrogen (N₂), oxygen (O₂), water vapor (H₂O), carbon dioxide (CO₂), carbon monoxide (CO), argon (Ar), helium (He), or combinations thereof.

Thus, in one instance, an incubated film can include regions having enhanced hydrophobic/hydrophilic differences between the incubated, exposed regions and the incubated, unexposed regions. Such differences can be advantageous, in that a hydrophilic condition (e.g., an aqueous developer, an alcohol, an acid, a base, gaseous water, oxygen (O₂), a gaseous acid, a gaseous halide, or a combination thereof) can be employed to remove more hydrophilic regions, and a hydrophobic condition (e.g., a ketone, an ester, an alcohol, an ether, or a combination thereof) can be employed to remove more hydrophobic regions. In any of these embodiments, wet or dry development conditions can be employed. In particular instances, developing includes a wet development process in conjunction with a dry development process. Such a process can include use of a ketone or liquid water with a gas including water, oxygen (O₂), a gaseous acid, a gaseous halide, or a combination thereof.

Returning to FIG. 1A, the method 100 can include developing 104 the incubated film, thereby either (i) removing the EUV exposed areas to provide a pattern within a positive tone resist film or (ii) removing the EUV unexposed areas to provide a pattern within a negative tone resist. Path (i) in FIG. 1A results in selectively removing the EUV exposed and incubated areas 112d, which can be facilitated by using organic co-reactant(s) that provide bound ligands that are less stable after EUV exposure (e.g., that release a gaseous by-product upon being exposed to EUV radiation) and/or by using incubating conditions that provide EUV exposed and incubated regions 112d to be more readily dissolved by a developer and/or by using incubating conditions that provide EUV unexposed and incubated regions 112e to be less readily dissolved by a developer. Alternatively, path (ii) in FIG. 1A results in maintaining the EUV exposed and incubated areas 112d, which can be facilitated by using organic co-reactant(s) that provide bound ligands that are more stable after EUV exposure (e.g., that are more resistant to development after EUV exposure) and/or by using incubating conditions that provide EUV exposed and incubated regions 112d to be less readily dissolved by a developer and/or by using incubating conditions that provide EUV unexposed regions and incubated 112e to be more readily dissolved by a developer.

Developing steps can include use of water vapor or halide chemistry (e.g., HBr chemistry) in a gas phase or use of aqueous or organic solvents in a liquid phase, as well as combinations thereof. In certain instances, wet development is employed, such as by use of water, an acid, a base, a ketone, an ester, an alcohol, an ether, a surfactant, or a combination thereof for an optional time period of about 15-120 seconds. In other instances, dry development is employed alone, or in combination with wet development (e.g., as sequential steps). Dry development can include, e.g., gaseous water, oxygen (O₂), a gaseous acid, a gaseous halide, or a combination thereof (e.g., water with acid; or O₂ with acid) for an optional time period of about 30-720 seconds at an optional pressure of about 0.1-1 Torr.

Developing steps can include any useful experimental conditions, such as a low pressure condition (e.g., of from about 1-100 mTorr), a plasma exposure (e.g., in the presence of vacuum), and/or a thermal condition (e.g., of from about −10-100° C.) that may be combined with any useful chemistry (e.g., halide chemistry or aqueous chemistry). Development can include, e.g., a halide-based etchant, such as hydrochloric acid (HCl), hydrobromic acid (HBr), hydrogen gas (H₂), chlorine gas (Cl₂), bromine gas (Br₂), boron trichloride (BCl₃), or combinations thereof, as well as any halide-based development process described herein; an aqueous alkali development solution; or an organic development solution. Additional development process conditions are described herein.

FIG. 1C-1E provides results for non-limiting films. The film included an organotin-based photoresist, which was exposed to varying radiation doses, incubated for two minutes at the indicated temperature, developed with the indicated developer for 10 seconds, and then rinsed for 10 seconds (with the same solvent as the developer). After development, the thickness of the film was measured for each exposed dose.

FIG. 1C shows the effect of differing incubation temperatures on a film that was developed with water (as the developer). As can be seen, incubating an exposed film at 175° C. improved DtG (3 mJ/cm²), as compared to a film incubated at 100° C. (DtG of 25-30 mJ/cm²).

FIG. 1D shows the use of 2-heptanone as the developer. As can be seen, increasing the incubation temperature resulted in an increase of DtG under the tested conditions. Delayed development (by four days) after incubation at 150° C. provided improved DtG (less than 15 mJ/cm²). FIG. 1E shows the use of isopropanol (IPA), water, or a mixture of IPA and water as the developer. Without wishing to be limited by mechanism, such solvent studies can be used to more fully elucidate the mechanism of film dissolution and to control solubility of various components of the film.

Optional steps may be conducted to further modulate, modify, or treat the EUV-sensitive film(s), substrate, photoresist layer(s), and/or in any method herein. FIG. 1B provides a flow chart of an exemplary method 150 having various operations, including optional operations. As can be seen, in operation 152, an organometallic precursor is provided in the presence of an organic co-reactant, which provides a modified precursor (e.g., within a chamber). In operation 154, a film is deposited employing the modified precursor. Next, operation 156 is an optional process to change the amount of the organometallic precursor and the organic co-reactant, thereby providing a further modified precursor. Such a change can include increasing or decreasing the amount of the organometallic precursor and/or the organic co-reactant. Optional operation 158 includes depositing the further modified precursor. Operations 156,158 can be repeated, as desired, to form a film having the modified precursor.

In operation 160, the film is exposed to EUV radiation to develop a pattern. Generally, the EUV exposure causes a change in the chemical composition of the film, creating a contrast in etch selectivity that can be used to remove a portion of the film. Such a contrast can provide a positive tone resist or a negative tone resist, as described herein.

In operation 162, the exposed film is incubated to further increase contrast in etch selectivity of the exposed film. In one instance, the exposed film can be incubated at a temperature of about 20-300° C. For example, incubation can include a low temperature for an extended period (e.g., about 20-30° C. or 20-35° C. for more than one day), an intermediate temperature for a short period (e.g., about 100-200° C. or 150-200° C. for less than 10 minutes), or an elevated temperature for a short period (e.g., about 100-300° C., 150-300° C., or 200-300° C. for less than 10 minutes). Such incubation (e.g., optionally in the presence of various chemical species) can promote reactivity within the EUV exposed portions or EUV unexposed regions of the resist upon exposure to a stripping agent (e.g., an aqueous development solution; gaseous water; oxygen (O₂); a gaseous acid; a gaseous halide; a halide-based etchant, such as HCl, HBr, H₂, C₁₂, Br₂, BCl₃, or combinations thereof, as well as any halide-based development process described herein; an organic development solution; or others described herein). In some embodiments, the exposed film can be thermally treated to further cross-link ligands within the EUV exposed portions of the resist, thereby providing EUV unexposed portions that can be selectively removed upon exposure to a stripping agent (e.g., a negative tone developer).

Then, in operation 164, the PR pattern is developed. In various embodiments of development, the exposed regions are removed (positive tone) or the unexposed regions are removed (negative tone). In various embodiments, these steps may be dry processes and/or wet processes. Dry processes can include a gas (e.g., including water, oxygen, acid, halide, or combinations thereof) for a time period of about 30-720 seconds and a pressure of about 0.1-1 Torr. Wet processes can include a liquid (e.g., water, an acid, a base, a ketone, an ester, an alcohol, an ether, or a combination thereof) for a time period of about 15-60 seconds and at room temperature (e.g., about 20-30° C. or 20-25° C.). In one instance, these steps can include a wet process followed by a dry process in any order. Such processes can be performed in cycles (e.g., alternating wet and dry processes for n number of cycles, in which n can be 1, 2, 3, 4, 5, or more).

Other optional steps may be performed. Optionally, the method can include (e.g., after deposition) cleaning the backside surface or bevel of the substrate or removing an edge bead of the deposited film that was deposited in the prior step. Such cleaning or removing steps can be useful for removing particles that may be present after depositing a film layer. The removing step can include processing the wafer with a wet metal oxide (MeOx) edge bead removal (EBR) step.

In another instance, the method can include an optional step of performing a post application bake (PAB) of the deposited film, thereby removing residual moisture; or pretreating the deposited film in any useful manner. The optional PAB can occur after film deposition and prior to EUV exposure; and the PAB can involve a combination of thermal treatment, chemical exposure, and moisture to increase the EUV sensitivity of the film, thereby reducing the EUV dose to develop a pattern in the film. In particular embodiments, the PAB step is conducted at a temperature greater than about 100° C. or at a temperature of from about 100-200° C. or from about 100-250° C. In some instances, a PAB is not performed within the method.

In yet another instance, the method can include an optional step of performing a post exposure bake (PEB) of the exposed film, thereby further removing residual moisture or promoting chemical condensation within the film; or post-treating the film in any useful manner. In another instance, the method can include (e.g., after development) hardening the patterned film, thereby providing a resist mask disposed on a top surface of the substrate. Hardening steps can include any useful process to further crosslink or react the EUV unexposed or exposed areas, such as steps of exposing to plasma (e.g., O₂, Ar, He, or CO₂ plasma), exposing to ultraviolet radiation, annealing (e.g., at a temperature of about 180-240° C.), thermal baking, or combinations thereof that can be useful for a post development baking (PDB) step. Additional post-application processes are described herein and may be conducted as an optional step for any method described herein.

Any useful type of chemistry can be employed during the depositing, patterning, and/or developing steps. Such steps may be based on dry processes employing chemistry in a gaseous phase or wet processes employing chemistry in a wet phase. Various embodiments include combining all dry operations of film formation by vapor deposition, (EUV) lithographic photopatterning, dry stripping, and dry development. Various other embodiments include dry processing operations described herein advantageously combined with wet processing operations, for example, spin-on EUV photoresists (wet process), such as available from Inpria Corp., may be combined with dry development or other wet or dry processes as described herein. In various embodiments, the wafer clean may be a wet process as described herein, while other processes are dry processes. In yet other embodiments, a wet development process may be used.

In some embodiments, dry processes are employed. For example, dry vapor deposition techniques described herein can be used to deposit thin and defect free films, in which the exact thickness of the deposited film can be modulated and controlled simply by increasing or decreasing the length of the deposition step or sequence. Accordingly, a dry process may provide tunability and give critical dimension (CD) control and scum removal. Dry development can improve performance (e.g., prevent line collapse), enhance throughput, reduce sensitivity to adhesion issues, improve line edge roughness, allow for direct patterning over device topography, and/or offer the ability to tune hardmask chemistry to the specific substrate and semiconductor device design. In other embodiments, a combination of wet and dry processes (e.g., processes such as deposition, development, or other treatment operations) are employed to provide such benefits. In yet other embodiments, wet processes (e.g., processes such as deposition, development, or other treatment operations) are employed to provide such benefits. Additional details, materials, processes, steps, and apparatuses are described herein.

### Modified Precursors

The present disclosure relates to use of organometallic precursor(s) in the presence of organic co-reactant(s) to generate a modified precursor, which in turn is immediately deposited to form a patterning radiation-sensitive film (e.g., an EUV-sensitive film). This film, in turn, can serve as an EUV resist, as further described herein. In particular embodiments, the modified precursor is generated and deposited in situ, e.g., generation occurs within the chamber for deposition.

The modified precursor can be a reaction product that is formed between the organometallic precursor and the organic co-reactant, in which the reaction product can then be deposited to form a film. Such reactions and depositions can be conducted in vapor form or in solvent (or liquid) form. In particular embodiments, the film can include one or more ligands (e.g., labile ligands) that can be removed, cleaved, or cross-linked by radiation (e.g., EUV or DUV radiation).

In some embodiments, use of carbon-containing co-reactants (or organic co-reactants) can expand the library of film compositions and enable tuning of the film of its various properties (e.g., mechanical properties of the film, optical properties such as patterning radiation sensitivity, and/or patterning performance). Such organic co-reactants can be used during the deposition process to decouple the density of radiation-sensitive elements and the density of radiation-responsive organic moieties in the film, which can allow tuning of the ratio of radiation-sensitive metal to radiation-responsive organic moieties that might lead to improved patterning radiation sensitivity and/or improved resultant patterning quality.

Furthermore, the organic co-reactant can be selected to instill other beneficial properties to the film. In one instance, the selected organic co-reactant can introduce a ligand to a metal center of the precursor, in which the introduced ligand is highly soluble to a positive tone developer upon exposure to patterning radiation. An illustrative ligand includes a bivalent oxalyl ligand located between metal centers, which provides a resilient film in radiation unexposed areas (e.g., EUV or DUV unexposed areas) but results in a removable film in radiation exposed areas (e.g., EUV or DUV exposed areas). In this way, the organic co-reactant can provide a positive tone resist. In another instance, the introduced ligand includes a polymerizable moiety (e.g., alkenylene, alkynylene, or epoxy) located between metal centers, which can undergo photopolymerization in radiation exposed areas. In this way, the organic co-reactant provides an enhanced negative tone resist.

The organometallic precursor can include any precursor (e.g., described herein) that provides a patternable film that is sensitive to radiation (or a patterning radiation-sensitive film or a photopatternable film). Such radiation can include EUV radiation or DUV radiation that is provided by irradiating through a patterned mask, thereby being a patterning radiation. The film itself can be altered by being exposed to such radiation, such that the film is radiation-sensitive. In particular embodiments, the organometallic precursor is an organometallic compound, which includes at least one metal center and at least one ligand that can react with the organic co-reactant. In this way, the organic moiety from the co-reactant reacts with or displaces the ligand from the metal center, thereby attaching that organic moiety as a bound ligand to the metal center. The organic moiety, itself, can enhance EUV/DUV sensitivity of the film (e.g., by increasing EUV/DUV absorptivity) or enhance contrast selectivity during development (e.g., by increasing porosity of a film). Furthermore, the organic moiety can be reactive in the presence of patterning radiation, such as by undergoing removal or elimination from the metal center or by reacting or polymerizing with other moieties within the film.

The organometallic precursor can have any useful number and type of ligand(s). As discussed herein, at least one ligand reacts with the organic co-reactant. A ligand can also be characterized by its ability to react in the presence of a counter-reactant or in the presence of patterning radiation. For instance, the organometallic precursor can include a ligand that reacts with a counter-reactant, which can introduce linkages between metal centers (e.g., an —O-linkage). Such a ligand (e.g., dialkylamino groups or alkoxy groups) could, in some instances, also react with an organic co-reactant. In another instance, the organometallic precursor can include a ligand that eliminates in the presence of patterning radiation. Such a ligand can include branched or linear alkyl groups having a beta-hydrogen.

The organometallic precursor can be any useful metal-containing precursor, such as an organometallic agent, a metal halide, or a capping agent (e.g., as described herein). In a non-limiting instance, the organometallic precursor includes a structure having formula (I):

MₐR_{b}L_{c} (I),
wherein:
   M is a metal or a metalloid;
   each R is, independently, halo, optionally substituted alkyl, optionally substituted aryl, optionally substituted amino, optionally substituted alkoxy, or L;
   each L is, independently, is a ligand, ion, or other moiety that is reactive with the organic co-reactant or a counter-reactant, in which R and L with M, taken together, can optionally form a heterocyclyl group or in which R and L, taken together, can optionally form a heterocyclyl group;

a≥1; b≥1; and c≥1.

In some embodiments, each ligand within the organometallic precursor can be one that is reactive with an organic co-reactant or a counter-reactant. In one instance, the organometallic precursor includes a structure having formula (I), in which each R is, independently, L. In another instance, the organometallic precursor includes a structure having formula (Ia):

MₐL_{c} (Ia),
wherein:
   M is a metal or a metalloid;
   each L is, independently, is a ligand, ion, or other moiety that is reactive with the organic co-reactant or a counter-reactant, in which two L, taken together, can optionally form a heterocyclyl group;

a≥1; and c≥1.

In particular embodiments of formula (Ia), a is 1. In further embodiments, c is 2, 3, or 4.

For any formula herein, M can be a metal or a metalloid with a high patterning radiation absorption cross-section (e.g., an EUV absorption cross-section that is equal to or greater than 1×10⁷ cm²/mol). In some embodiments, M is tin (Sn), tellurium (Te), bismuth (Bi), antimony (Sb), hafnium (Hf), or zirconium (Zr). In further embodiments, M is Sn, a is 1, and c is 4 in formula (I) or (Ia). In other embodiments, M is Sn, a is 1, and c is 2 in formula (I) or (Ia). In particular embodiments, M is Sn(II) (e.g., in formula (I) or (Ia)), thereby providing an organometallic precursor that is a Sn(II)-based compound. In other embodiments, M is Sn(IV) (e.g., in formula (I) or (Ia)), thereby providing an organometallic precursor that is a Sn(IV)-based compound.

For any formula herein, each L is, independently, H, halo, optionally substituted alkyl, optionally substituted aryl, optionally substituted amino, optionally substituted bis(trialkylsilyl)amino, optionally substituted trialkylsilyl, or optionally substituted alkoxy (e.g.,

—OR¹, in which R¹ can be alkyl). In some embodiments, the optionally substituted amino is —NR¹R², in which each R¹ and R² is, independently, H or alkyl; or in which R¹ and R², taken together with the nitrogen atom to which each are attached, form a heterocyclyl group, as defined herein. In other embodiments, the optionally substituted bis(trialkylsilyl)amino is —N(SiR¹R²R³)₂, in which each R¹, R², and R³ is, independently, alkyl. In yet other embodiments, the optionally substituted trialkylsilyl is —SiR¹R²R³, in which each R¹, R², and R³ is, independently, alkyl.

In other embodiments, the formula includes a first L that is —NR¹R² and a second L that is —NR¹R², in which each R¹ and R² is, independently, H or alkyl; or in which R¹ from a first L and R¹ from a second L, taken together with the nitrogen atom and the metal atom to which each are attached, form a heterocyclyl group, as defined herein. In yet other embodiments, the formula includes a first L that is —OR¹ and a second L that is —OR¹, in which each R¹ is, independently, H or alkyl; or in which R¹ from a first L and R¹ from a second L, taken together with the oxygen atom and the metal atom to which each are attached, form a heterocyclyl group, as defined herein.

In some embodiments, at least one of L or R is optionally substituted alkyl (e.g., in formula (I) or (Ia)). Non-limiting alkyl groups include, e.g., CₙH₂ₙ₊₁, where n is 1, 2, 3, or greater, such as methyl, ethyl, n-propyl, isopropyl, n-butyl, isobutyl, s-butyl, or t-butyl. In various embodiments, L or R has at least one beta-hydrogen or beta-fluorine. In particular, the organometallic precursor can be tetramethyl tin (SnMe₄), tetraethyl tin (SnEt₄), t-butyl tellurium hydride (Te(t-Bu)(H)), dimethyl tellurium (TeMe₂), di(t-butyl) tellurium (Te(t-Bu)₂), or di(isopropyl)tellurium (Te(i-Pr)₂).

In some embodiments, each L or at least one L is halo (e.g., in formula (I) or (Ia)). In particular, the organometallic precursor can be a metal halide. Non-limiting metal halides include SnBr₄, SnCl₄, SnI₄, and SbCl₃.

In some embodiments, each L or at least one L can include a nitrogen atom. In particular embodiments, one or more L can be optionally substituted amino or optionally substituted bis(trialkylsilyl)amino (e.g., in formula (I) or (Ia)). Non-limiting L substituents can include, e.g., —NMe₂, -NEt₂, —NMeEt, —N(t-Bu)-[CHCH_{3]2}—N(t-Bu)— (tbba), —N(SiMe₃)₂, and —N(SiEt₃)₂. Non-limiting organometallic precursors can include, e.g., Sn(NMe₂)₄, Sn(NEt₂)₄, Sn(i-Pr)(NMe₂)₃, Sn(n-Bu)(NMe₂)₃, Sn(s-Bu)(NMe₂)₃, Sn(i-Bu)(NMe₂)₃, Sn(t-Bu)(NMe₂)₃, Sn(t-Bu)₂(NMe₂)₂, Sn(t-Bu)(NEt₂)₃, Sb(NMe₂)₃, Sn(tbba), Sn[N(SiMe₃)₂]₂, or Bi[N(SiMe₃)₂]₃.

In some embodiments, each L or at least one L can include a silicon atom. In particular embodiments, one or more L can be optionally substituted trialkylsilyl or optionally substituted bis(trialkylsilyl)amino (e.g., in formula (I) or (Ia)). Non-limiting L substituents can include, e.g., —SiMe₃, —SiEt₃, —N(SiMe₃)₂, and —N(SiEt₃)₂. Non-limiting organometallic precursors can include, e.g., Sn[N(SiMe₃)₂]₂, bis(trimethylsilyl)tellurium (Te(SiMe₃)₂), bis(triethylsilyl) tellurium (Te(SiEt₃)₂), or Bi[N(SiMe₃)₂]₃.

In some embodiments, each L or at least one L can include an oxygen atom. In particular embodiments, one or more L can be optionally substituted alkoxy (e.g., in formula (I) or (Ia)). Non-limiting L substituents include, e.g., methoxy, ethoxy, isopropoxy (i-PrO), t-butoxy (t-BuO), and —O═C(CH₃)—CH═C(CH₃)—O— (acac). Non-limiting organometallic precursors include, e.g., Sn(t-BuO)₄, Sn(n-Bu)(t-BuO)₃, or Sn(acac)₂.

Yet other organometallic precursors and non-limiting substituents are described herein. For instance, organometallic precursors can be any having a structure of formulas (I) and (Ia), as described above; or formulas (III), (IV), (V), (VI), (VII), or (VIII), as described below. Any of the substituents M, R, X, or L, as described herein, can be employed in any of formulas (I), (Ia), (III), (IV), (V), (VI), (VII), or (VIII).

To provide a modified precursor, an organic co-reactant is employed to react with or to replace a ligand of the organometallic precursor. Any useful organic co-reactant can be employed. Such an organic co-reactant can be provided in any form, e.g., as a vapor phase.

In one non-limiting instance, the organic co-reactant is a compound having formula (II):

X¹—Z—X² (II),

wherein:
each of X¹ and X² is, independently, a leaving group (e.g., halo, H, hydroxyl, optionally substituted alkyl, optionally substituted alkoxy, etc.); and
Z is carbonyl, dicarbonyl, optionally substituted alkylene, optionally substituted haloalkylene, optionally substituted alkenylene, or optionally substituted alkynylene.

In some embodiments, Z is substituted with one or more oxo (═O) groups. In particular embodiments, Z is oxalyl, mesoxalyl, malonyl, or oxalacetyl. In other embodiments, Z includes one or more saturated bonds. In particular embodiments, Z is ethynylene. Examples of organic co-reactants include oxalyl chloride, acetylene, and others, as well as derivatives thereof. In other embodiments, Z is substituted with one or more halo groups.

In some embodiments, the organic co-reactant is an acetylene derivative having formula (IIa):

X¹—C≡C—H (IIa),

wherein:
X¹ is a leaving group, such as halo, H, or optionally substituted alkyl.

In other embodiments, the organic co-reactant is a carbonyl-containing derivative having formula (IIb):

X¹—C(O)—X² (IIb),

wherein:
each of X¹ and X² is, independently, a leaving group, such as halo, H, hydroxyl, optionally substituted alkyl, or optionally substituted alkoxy.

In other embodiments, the organic co-reactant is an oxalyl derivative having formula (IIc):

X¹—C(O)—C(O)—X² (IIc),

wherein:
each of X¹ and X² is, independently, a leaving group, such as halo, H, hydroxyl, optionally substituted alkyl, or optionally substituted alkoxy.

In yet other embodiments, the organic co-reactant is an alkyl derivative having formula (IId):

X¹-Ak-H (IId),

wherein:
X¹ is a leaving group, such as halo, hydroxyl, optionally substituted alkyl, or optionally substituted alkoxy; and
Ak is an optionally substituted alkylene or optionally substituted haloalkylene.
   When at least one halo is present, then the organic co-reactant can be a haloalkyl moiety or a haloalkyl derivative. In particular embodiments, the organic co-reactant is a haloalkyl derivative (e.g., in which halo is iodo), and the organometallic precursor is a Sn(II)-based compound.

Without wishing to be limited by mechanism, the modified precursor obtained by using such compounds can involve oxidative addition of a low valent Sn(II) species or other electron rich metallic precursor across a reactive carbon-halogen bond of the added organic co-reactant (e.g., provided in vapor phase). In some instance, the reactive carbon-halogen bond is a reactive carbon-iodine bond. Non-limiting alkyl derivatives include ethyl iodide, iso-propyl iodide, t-butyl iodide, diiodomethane, etc.

In some instances, the electron rich metallic precursor is a trivalent Sb or Bi precursor. Non-limiting precursors can include SbR₃ or BiR₃ (e.g., R is any described herein, such as a for formula (I), (IV), or (VI)), to which an alkyl halide could add to form a pentavalent complex. Of note, Sb and Bi are of interest due to their high EUV absorption cross section.

Methods can also employ a chalcogenide precursor, as a counter-reactant or an organic co-reactant. In particular embodiments, the chalcogenide precursor includes a structure having formula (IIe):

X³—Z—X⁴ (IIe),
wherein:
   Z is sulfur, selenium, or tellurium; and
   each of X³ and X⁴ is, independently, H, optionally substituted alkyl (e.g., methyl, ethyl, n-propyl, isopropyl, n-butyl, t-butyl, etc.), optionally substituted alkenyl, optionally substituted aryl, optionally substituted amino, optionally substituted alkoxy, or optionally substituted trialkylsilyl.

The organic co-reactant can be employed to replace at least one ligand of the organometallic precursor, in which the organic co-reactant provides a bound ligand for the modified precursor. In one instance, the organic co-reactant can include a structure having formula (II), and the bound ligand can include or be any useful substituent resulting from a reaction between the organometallic precursor and the organic co-reactant (optionally with a counter-reactant). In particular embodiments, the bound ligand in the modified precursor has a structure of —X^{a}—Z—X^{b}—, in which Z can be optionally substituted alkylene, optionally substituted alkenylene, or optionally substituted alkynylene (e.g., ethynylene, oxalyl, mesoxalyl, malonyl, or oxalacetyl); and each of X^{a} and X^{b} is, independently, a bond (e.g., a covalent bond), oxy, imino, or carbonyl. In other embodiments, the bound ligand in the modified precursor has a structure of —X^{a}—Z—X^{c}, in which Z can be optionally substituted alkylene, optionally substituted alkenylene, or optionally substituted alkynylene (e.g., ethynylene, oxalyl, mesoxalyl, malonyl, or oxalacetyl); X^{a} is, independently, a bond (e.g., a covalent bond), oxy, imino, or carbonyl; and X° is halo, H, hydroxyl, optionally substituted alkyl, or optionally substituted alkoxy.

In some embodiments, the organic co-reactant includes one or more bulky substituents, thereby providing a modified precursor having a bound ligand that includes a bulky substituent. In one instance, a bulky organic co-reactant might lead to increased dry development contrast in the film, due to an increased porosity difference between radiation exposed and unexposed areas. In another instance, a bulky organic co-reactant might lead to increased dry development rate due to increased porosity difference between radiation exposed and unexposed areas. In general, bulkier substituents may provide films having increased porosity, and increased porosity would provide increased access to etchant or development chemistries. Porosity can be characterized in any useful manner, e.g., such as a volumetric gas adsorption.

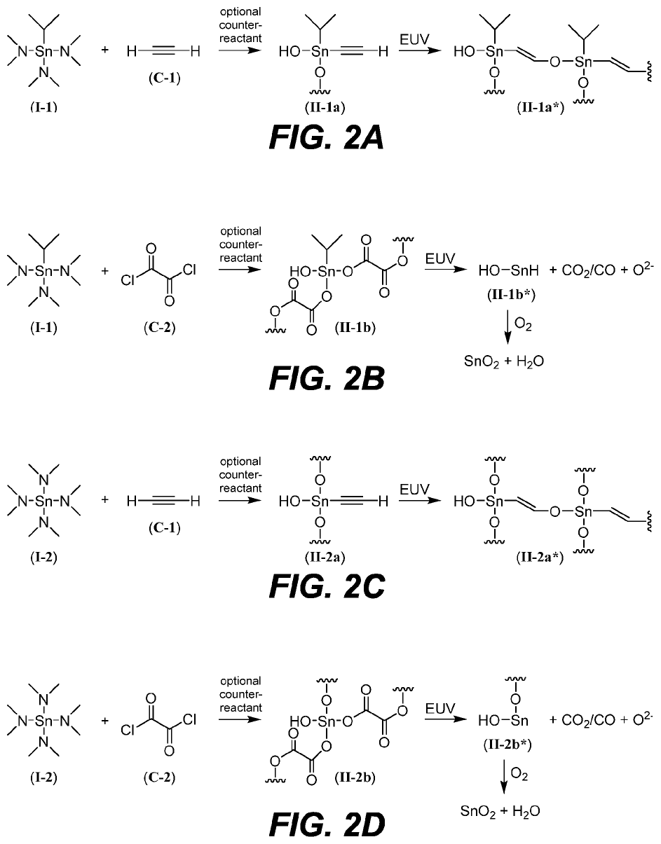

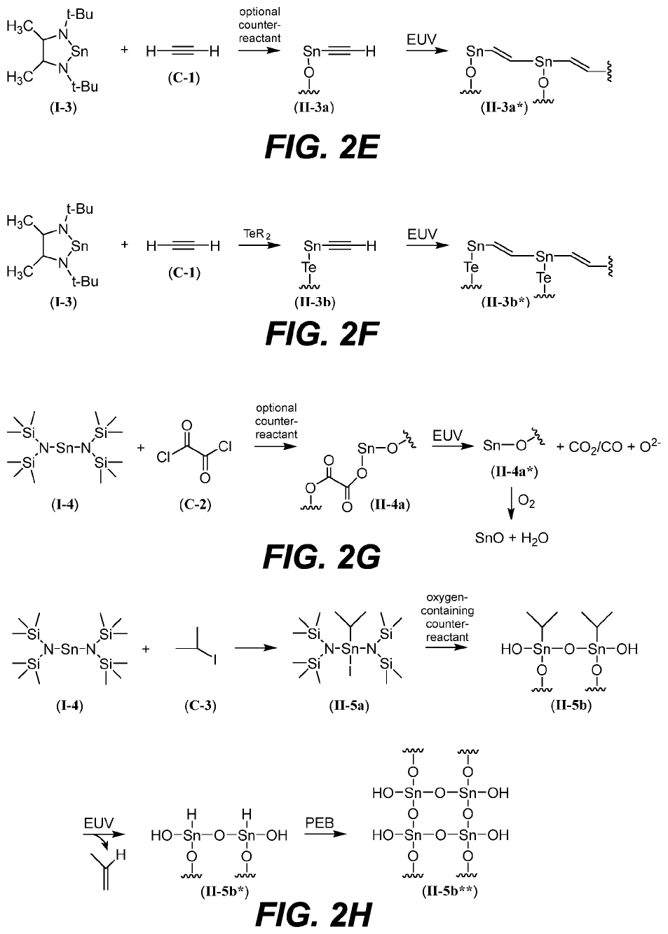

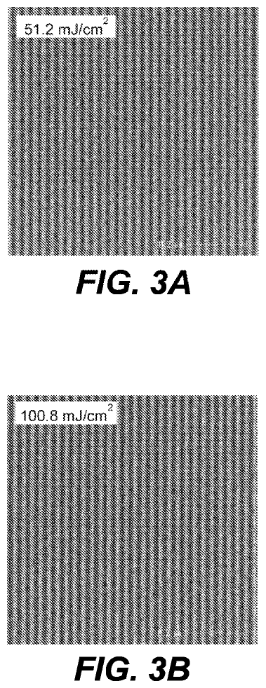

FIG. 2A shows a non-limiting embodiment of an organometallic precursor in the presence of an organic co-reactant. As can be seen, the non-limiting organometallic precursor can be a tin-based compound (Sn(i-Pr)(NMe₂)₃, I-1) provided in the presence of a non-limiting organic co-reactant, e.g., acetylene (C-1). As can be seen, the organometallic precursor has a ligand (e.g., —NMe₂) that can be replaced with the organic co-reactant, thereby providing a modified precursor having formula (II-1a) that can be deposited as a film. As can be seen, the isopropyl group of the organometallic precursor can be maintained in the modified precursor, and reactive —NMe₂ ligands can form any useful chemical bonds. For instance, the reactive ligand can result in a terminal —OH moiety or a Sn—O bond, such as by reacting with an optional oxygen-containing counter-reactant; and the reactive ligand can react with the organic co-reactant to provide a bound ligand (herein, in formula (II-1a), the bound ligand is —C≡CH).

As can be seen, a modified precursor can include any useful chemical bonds within the film. Non-limiting bonds include terminal —OH moieties (e.g., as a result of reacting with one or more counter-reactants); one or more metal-oxygen-metal (M-O-M) bonds, which can be formed between metal centers of precursors; one or more bonds resulting in a metal-carbon (M-C) bond between the metal center and an atom within the bound ligand provided by the organic co-reactant; and/or one or more bonds resulting in a metal-oxygen (M-O) bond between the metal center and an atom within the bound ligand provided by the organic co-reactant.

The approaches herein can provide improved modified precursors and/or improved films. For instance, state-of-the-art metal oxide EUV photoresists are generally produced from organometallic precursors having a high EUV-sensitivity element (e.g., Sn) and an EUV-responsive organic moiety directly bonded to the metal center (e.g., methyl, ethyl, n-propyl, isopropyl, n-butyl, sec-butyl, tert-butyl, etc.). This precursor is optionally reacted in situ with a counter-reactant, such as water. As such, the resultant density of EUV-sensitive elements and EUV-sensitive organic moieties are directly coupled together by the intrinsic nature of the organometallic precursor. In contrast, the present disclosure allows for the density of EUV-sensitive elements and the density of EUV-responsive organic moieties to be modulated without requiring change of the organometallic precursor. In this way, different chemistries can be readily accessed by modulating the extent of reaction between the organometallic precursor and the organic co-reactant (e.g., by modulating the amount of the organometallic precursor and/or the co-reactant, the reaction time between these two compounds, and the like) and by decoupling of the density of EUV-sensitive elements and the density of EUV-responsive organic moieties within the film.

For instance, this approach can yield EUV-sensitive films with a tunable metal to carbon ratio. In one embodiment, such tuning can provide films having higher EUV responsivity than currently available photoresist (PR), thus increasing wafer patterning throughput. In other embodiments, this process could provide a tuning knob to change the dose-to-size, optimize patterning quality (e.g., enhanced line-width-roughness (LWR) and/or line-edge-roughness (LER)), and/or improve mechanical strength. Such tuning can occur between deposition of two films (e.g., thereby producing two films with differing metal to carbon ratio) or within the same film (e.g., thereby providing a single film with a gradient in metal to carbon ratio). For instance, the approaches herein could allow for a gradient density of EUV-responsive organic moieties within the film. Without wishing to be limited by mechanism, since more photons are available for absorption nearer the surface of the PR and fewer photons reach the bottom, a gradient density of EUV-sensitive organic moieties might allow for greater homogenization of EUV absorption events, making development processes more reliable and more readily optimized.

Additionally, the physical size of the organic co-reactant might yield films with increased porosity in areas that are not exposed, which would allow for the improved diffusion of gases involved in dry development into unexposed areas while reduced diffusion of dry development gases may occur in exposed areas. As a result of this difference in porosity, dry development of such films in a negative tone scheme might yield higher contrast between exposed and unexposed areas.

Furthermore, this approach can provide films that can be processed with negative tone dry development strategies or positive tone wet development strategies, in which the organometallic precursor can be maintained and changing the organic co-reactant changes the type of film produced. Depending on the chemical structure of the ligand provided by reacting the organic co-reactant with the organometallic precursor, radiation exposure can result in stabilizing or destabilizing the film. As seen in FIG. 2A, after depositing the modified precursor, the resultant film can be exposed to EUV radiation. In one instance, EUV exposure can result in photopolymerized cross-linking between the bound ethynyl ligands, thereby providing a stabilized, cross-linked film (II-1a*). For example, the use of acetylene might yield high performance, negative tone patterning as a result of EUV-induced polymerization followed by dry development. In some non-limiting instances, incubating such a film at an increased temperature (e.g., from 100-300° C.) can result in further crosslinking within EUV exposed regions. Without wishing to be limited by mechanism, such crosslinking can be promoted by increased Sn—O bond formation and/or increased crosslinking between organic ligands. In other instances, incubating such a film at an increased temperature (e.g., from 100-300° C.) can result in thermal decomposition of ethynyl or ethenyl.

In another instance, radiation exposure can degrade areas within the film, and such a modified precursor can provide a positive tone photoresist. FIG. 2B shows use of oxalyl chloride (as an organic co-reactant), which might yield high performance positive tone patterning using EUV via wet development strategies. Inclusion of oxalyl bridging groups may yield unexposed films that are resilient to positive tone wet developers (e.g., tetramethylammonium hydroxide), resulting in high contrast positive tone PR.

As seen in FIG. 2B, a non-limiting organometallic precursor (Sn(i-Pr)(NMe₂)₃, I-1) is provided in the presence of oxalyl chloride (C-2) to provide a modified precursor having formula (II-1b). For this modified precursor, the bound ligand includes an oxalyl substituent (—C(O)C(O)—) provided by the organic co-reactant and an oxy substituent (—O—), which can be provided by an oxygen-containing counter-reactant. Upon exposure to EUV radiation, the bound ligand within the modified precursor can be degraded, thereby producing a metal hydroxide (II-1b*) and carbon dioxide. Further treatment of EUV exposed areas with oxygen can provide a further metal oxide film.

In some instances, inclusion of radiation-responsive organic moieties by using an organic co-reactant may result in films that do not require post-exposure treatment to cross-link the metal species. For instance, when employing an oxalyl derivative, the bound ligand may provide a film having an oxalyl substituent that does not require post-exposure treatment. Such a film may possess improved patterning quality (e.g., improved LWR and/or LER) by reducing bake-related blurring effects and/or increased wafer patterning throughput.

In other instances, radiation exposed films can be further developed using development processes described herein. In some embodiments, the film can be dry developed in one or more steps involving halide chemistry (e.g., HBr, HCl, and/or BCl₃). In other embodiments, the film can be developed with wet chemistry. For instance and without limitation, use of oxalyl chloride as an organic co-reactant can yield superior positive tone wet development performance arising from oxalate linkages between metal centers, which are expected to be resilient to positive tone developers (e.g., an aqueous alkaline developer, such as tetramethylammonium hydroxide (TMAH), or other wet developers described herein).

Methods herein also include the use of an organometallic precursor having only ligands that are reactive with the organic co-reactant or a counter-reactant. In this way, organic moieties are solely introduced into a deposited film by the organic co-reactant. For instance, FIG. 2C shows use of an organometallic precursor (Sn(NMe₂)₄, I-2) having only reactive ligands (e.g., —NMe₂), each of which can be reactive with an organic co-reactant and/or a counter-reactant. In use with acetylene (C-1) as the organic co-reactant, the modified precursor (II-2a) can include bound ligands (e.g., —C≡CH), hydroxyl moieties, and other metal-oxy bonds. As can be seen, carbon content within this film is provided entirely by the organic co-reactant.

Upon exposure to patterning radiation, the bound ligand within the modified precursor can be cross-linked, thereby providing a film having structure (II-2a*). In another instance, FIG. 2D shows use of an organometallic precursor (Sn(NMe₂)₄, I-2) in the presence of oxalyl chloride (C-2) to provide a modified precursor (II-2b) including bound ligands (e.g., —OC(O)C(O)O—), hydroxyl moieties, and other metal-oxy bonds. EUV exposure can provide a film (II-2b*) that releases a gaseous byproduct (e.g., carbon dioxide and/or carbon monoxide).

By decoupling the source of metal centers and organic moieties, various organometallic precursors can be employed. For instance, FIG. 2E-2H shows use of an organometallic precursor having a tin(II) metal center. As seen in FIG. 2E, the organometallic precursor can be Sn(II)(tbba) (I-3) employed in the presence of acetylene (C-1) to provide a modified precursor (II-3a) having a photopolymerizable bound ligand, in which EUV exposure can provide a cross-linked film (II-3a*).

The organometallic precursor and organic co-reactant can be reacted by oxidative addition with a chalcogenide precursor (e.g., TeR₂). As seen in FIG. 2F, an organometallic precursor of Sn(II)(tbba) (I-3) can be employed in the presence of acetylene (C-1) and Te-containing precursor to provide a modified precursor (II-3b) having a photopolymerizable bound ligand and Sn—Te bonds, in which EUV exposure can provide a cross-linked film (II-3b*). Non-limiting Te-containing precursors include any described herein, such as TeR₂ in which R can be H, optionally substituted alkyl, or optionally substituted trialkylsilyl.

FIG. 2G shows an organometallic precursor (Sn[N(SiMe₃)₂]₂, I-4) for use in the presence of oxalyl chloride (C-2), which can provide a modified precursor (II-4a). The resulting film can then be exposed to EUV to provide an exposed film (II-4a*).

Sn(II)-based precursors can be reacted with an organic co-reactant to provide an Sn(IV)-based modified precursor for deposition. For instance, FIG. 2H shows that organometallic precursor (I-4) can be employed in the presence of an alkyl halide (e.g., isopropyl iodide, C-3) to provide a modified precursor (II-5a) having a Sn(IV) metal center. As can be seen, in this way, the organic co-reactant can be used with an electron-rich Sn(II) precursor to incorporate an EUV labile alkyl group (e.g., isopropyl, t-butyl, etc.) and an EUV absorption-enhancing ligand (e.g., iodide) into the modified precursor. The resulting film can then be treated with an oxygen-containing counter-reactant to provide an organometal oxide film (II-5b), which in turn can be exposed to EUV to provide an exposed film (II-5b*) and release the cleaved alkyl group (e.g., propylene, when the labile alkyl group is isopropyl). Then, the exposed film can be baked to provide a metal oxide film (II-5b**).

Such EUV-absorbing and EUV-sensitive materials can be deposited in any useful manner, as described herein. Exemplary deposition techniques include atomic layer deposition (ALD) (e.g., thermal ALD and plasma-enhanced ALD (PE-ALD)), spin-coat deposition, physical vapor deposition (PVD) including PVD co-sputtering, chemical vapor deposition (CVD), plasma enhanced CVD (PE-CVD), low pressure CVD (LP-CVD), sputter deposition, electron-beam (e-beam) deposition including e-beam co-evaporation, etc., or a combination thereof. Other deposition processes and conditions are described herein.

One or more precursor(s) and one or more organic co-reactant(s) can be further used in any useful combination. For example, different combinations of precursors and organic co-reactants can be employed to tune the composition of the deposited resist film and their resulting properties. In one instance, DtS can be modulated by mixing different precursors. For instance, as seen in FIG. 3A, the use of a first tin-containing precursor including a first alkyl group, a second tin-containing precursor including a second alkyl group (in which the first and second alkyl groups are different), and acetone as the organic co-reactant provided a resist film (e.g., a mixed alkyl film) having a DtS of 51.2 mJ/cm² for HP 14. Using the same first tin-containing precursor with acetone as the organic co-reactant (thereby omitting the second tin-containing precursor), the DtS increased to 100.8 mJ/cm² for HP 14 in the resist film (e.g., a single alkyl film) (see FIG. 3B). Both films were exposed to a post-exposure bake.

Using such modified precursors (including one or more organometallic precursors with an organic co-reactant), incubation or baking can be used to modify properties of the resist film. In one instance, DtS can be modulated (e.g., lowered or increased) by incubating a deposited film at elevated temperatures. In one non-limiting example, by using the same film with differing PEB conditions (e.g., differing PEB temperatures), DtS can be modulated.

Such precursor(s) and organic co-reactant(s) can be further used in combination with one or more counter-reactants. Counter-reactants preferably have the ability to replace the reactive moieties, ligands, or ions (e.g., L in formulas herein) so as to link at least two metal atoms via chemical bonding. Exemplary counter-reactants include oxygen-containing counter-reactants, such as O₂, O₃, water, peroxides (e.g., hydrogen peroxide), oxygen plasma, water plasma, alcohols, di- or polyhydroxy alcohols, fluorinated di- or polyhydroxy alcohols, fluorinated glycols, formic acid, and other sources of hydroxyl moieties, as well as combinations thereof. In various embodiments, a counter-reactant reacts with the organometallic precursor or the modified precursor by forming oxygen bridges between neighboring metal atoms. Other potential counter-reactants include hydrogen sulfide and hydrogen disulfide, which can crosslink metal atoms via sulfur bridges and bis(trimethylsilyl)tellurium, which can crosslink metal atoms via tellurium bridges. In addition, hydrogen iodide may be utilized to incorporate iodine into the film.

Various atoms present in the organic co-reactant and/or counter-reactant can be provided within a gradient film. In some embodiments of the techniques discussed herein, a non-limiting strategy that can further improve the EUV sensitivity in a PR film is to create a film in which the film composition is vertically graded, resulting in depth-dependent EUV sensitivity. In a homogenous PR with a high absorption coefficient, the decreasing light intensity throughout the film depth necessitates a higher EUV dose to ensure the bottom is sufficiently exposed. By increasing the density of atoms with high EUV absorptivity at the bottom of the film relative to the top of the film (i.e., by creating a gradient with increasing EUV absorption), it becomes possible to more efficiently use available EUV photons while more uniformly distributing absorption (and the effects of secondary electrons) towards the bottom of more highly absorbing films. In one non-limiting instance, the gradient film includes Te, I, or other atoms towards the bottom of the film (e.g., closer to the substrate).

The strategy of engineering a vertical composition gradient in a PR film is particularly applicable to dry deposition methods, such as CVD and ALD, and can be realized by tuning the flow ratios between different reactants during deposition. The type of composition gradients that can be engineered include: the ratios between different high-absorbing metals, the percentage of metal atoms that have EUV-cleavable organic groups, the percentages of organic co-reactants and/or counter-reactants that contain high-absorbing elements, and combinations of the above.

The composition gradient in the EUV PR film can also bring additional benefits. For instance, high density of high-EUV-absorbing elements in the bottom part of the film can effectively generate more secondary electrons that can better expose upper portions of the film. In addition, such compositional gradients can also be directly correlated with a higher fraction of EUV absorbing species that are not bonded to bulky, terminal substituents. For example, in the case of Sn-based resists, the incorporation of tin precursors with four leaving groups is possible, thereby promoting the formation of Sn—O-substrate bonding at the interface for improved adhesion.

Such gradient films can be formed by using any organometallic precursors (e.g., tin or non-tin precursors), organic co-reactants, counter-reactants, and/or modified precursors described herein. Yet other films, methods, precursors, and other compounds are described in U.S. Provisional Pat. Appl. No. 62/909,430, filed Oct. 2, 2019, and International Appl. No. PCT/US20/53856, filed Oct. 1, 2020, and published as WO 2021/067632, each of which is titled SUBSTRATE SURFACE MODIFICATION WITH HIGH EUV ABSORBERS FOR HIGH PERFORMANCE EUV PHOTORESISTS; and International Appl. No. PCT/US20/70172, filed Jun. 24, 2020, published as WO 2020/264557, and titled PHOTORESIST WITH MULTIPLE PATTERNING RADIATION-ABSORBING ELEMENTS AND/OR VERTICAL COMPOSITION GRADIENT, the disclosures of which at least relating to the composition, deposition, and patterning of directly photopatternable metal oxide films to form EUV resist masks are incorporated by reference herein.

Furthermore, two or more different precursors can be employed within each layer (e.g., a film or a capping layer). For instance, two or more of any metal-containing precursors herein can be employed to form an alloy. In one non-limiting instance, tin telluride can be formed by employing tin precursor including an —NR₂ ligand with RTeH, RTeD, or TeR₂ precursors, in which R is an alkyl, particularly t-butyl or i-propyl. In another instance, a metal telluride can be formed by using a first metal precursor including an alkoxy or a halo ligand (e.g., SbCl₃) with a tellurium-containing precursor including a trialkylsilyl ligand (e.g., bis(trimethylsilyl)tellurium).

Yet other exemplary EUV-sensitive materials, as well as processing methods and apparatuses, are described in U.S. Pat. No. 9,996,004 and Int. Pat. Pub. No. WO 2019/217749, each of which is incorporated herein by reference in its entirety.

### Further Precursors

As described herein, the films, layers, and methods herein can be employed with any useful precursor. In some instances, the organometallic precursor includes a metal halide having the following formula (III):

MXₙ (III),

in which M is a metal, X is halo, and n is 2 to 4, depending on the selection of M. Exemplary metals for M include Sn, Te, Bi, or Sb. Exemplary metal halides include SnBr₄, SnCl₄, SnI₄, and SbCl₃.

Another non-limiting metal-containing precursor includes a structure having formula (IV):

MRₙ (IV),

in which M is a metal; each R is independently H, an optionally substituted alkyl, amino (e.g., —NR₂, in which each R is independently alkyl), optionally substituted bis(trialkylsilyl)amino (e.g., —N(SiR₃)₂, in which each R is independently alkyl), or an optionally substituted trialkylsilyl (e.g., —SiR₃, in which each R is independently alkyl); and n is 2 to 4, depending on the selection of M. Exemplary metals for M include Sn, Te, Bi, or Sb. The alkyl group may be CₙH₂ₙ₊₁, where n is 1, 2, 3, or greater. Exemplary organometallic agents include SnMe₄, SnEt₄, TeRn, RTeR, t-butyl tellurium hydride (Te(t-Bu)(H)), dimethyl tellurium (TeMe₂), di(t-butyl) tellurium (Te(t-Bu)₂), di(isopropyl)tellurium (Te(i-Pr)₂), bis(trimethylsilyl)tellurium (Te(SiMe₃)₂), bis(triethylsilyl) tellurium (Te(SiEt₃)₂), tris(bis(trimethylsilyl)amido) bismuth (Bi[N(SiMe₃)₂]₃), Sb(NMe₂)₃, and the like.

Another non-limiting metal-containing precursor can include a capping agent having the following formula (V):

MLₙ (V),

in which M is a metal; each L is independently an optionally substituted alkyl, amino (e.g., —NR¹R², in which each of R¹ and R² can be H or alkyl, such as any described herein), alkoxy (e.g., —OR, in which R is alkyl, such as any described herein), halo, or other organic substituent; and n is 2 to 4, depending on the selection of M. Exemplary metals for M include Sn, Te, Bi, or Sb. Exemplary ligands include dialkylamino (e.g., dimethylamino, methylethylamino, and diethylamino), alkoxy (e.g., t-butoxy, and isopropoxy), halo (e.g., F, Cl, Br, and I), or other organic substituents (e.g., acetylacetone or N²,N³-di-tertbutyl-butane-2,3-diamino). Non-limiting capping agents include SnCl₄; SnI₄; Sn(NR₂)₄, wherein each of R is independently methyl or ethyl; or Sn(t-BuO)₄. In some embodiments, multiple types of ligands are present.

A metal-containing precursor can include a hydrocarbyl-substituted capping agent having the following formula (VI):

RₙMXₘ (VI),

wherein M is a metal, R is a C₂₋₁₀ alkyl or substituted alkyl having a beta-hydrogen, and X is a suitable leaving group upon reaction with a hydroxyl group of the exposed hydroxyl groups. In various embodiments, n=1 to 3, and m=4−n, 3−n, or 2−n, so long as m>0 (or m≥1). For example, R may be t-butyl, t-pentyl, t-hexyl, cyclohexyl, isopropyl, isobutyl, sec-butyl, n-butyl, n-pentyl, n-hexyl, or derivatives thereof having a heteroatom substituent in the beta position. Suitable heteroatoms include halogen (F, Cl, Br, or I), or oxygen (—OH or —OR). X may be dialkylamino (e.g., dimethylamino, methylethylamino, or diethylamino), alkoxy (e.g., t-butoxy, isopropoxy), halo (e.g., F, Cl, Br, or I), or another organic ligand. Examples of hydrocarbyl-substituted capping agents include t-butyltris(dimethylamino)tin (Sn(t-Bu)(NMe₂)₃), n-butyltris(dimethylamino)tin (Sn(n-Bu)(NMe₂)₃), t-butyltris(diethylamino)tin (Sn(t-Bu)(NEt₂)₃), di(t-butyl)di(dimethylamino)tin (Sn(t-Bu)₂(NMe₂)₂), sec-butyltris(dimethylamino)tin (Sn(s-Bu)(NMe₂)₃), n-pentyltris(dimethylamino)tin (Sn(n-pentyl)(NMe₂)₃), i-butyltris(dimethylamino) tin (Sn(i-Bu)(NMe₂)₃), i-propyltris(dimethylamino)tin (Sn(i-Pr)(NMe₂)₃), t-butyltris(t-butoxy)tin (Sn(t-Bu)(t-BuO)₃), n-butyl(tris(t-butoxy)tin (Sn(n-Bu)(t-BuO)₃), or isopropyltris(t-butoxy)tin (Sn(i-Pr)(t-BuO)₃).

In various embodiments, a metal-containing precursor includes at least one alkyl group on each metal atom that can survive the vapor-phase reaction, while other ligands or ions coordinated to the metal atom can be replaced by the counter-reactants. Accordingly, another non-limiting metal-containing precursor includes an organometallic agent having the formula (VII):

MₐR_{b}L_{c} (VII),

in which M is a metal; R is an optionally substituted alkyl; L is a ligand, ion, or other moiety which is reactive with the counter-reactant; a≥1; b≥1; and c≥1. In particular embodiments, a=1, and b+c=4. In some embodiments, M is Sn, Te, Bi, or Sb. In particular embodiments, each L is independently amino (e.g., —NR¹R², in which each of R¹ and R² can be H or alkyl, such as any described herein), alkoxy (e.g., —OR, in which R is alkyl, such as any described herein), or halo (e.g., F, Cl, Br, or I). Exemplary agents include SnMe₃Cl, SnMe₂Cl₂, SnMeCl₃, SnMe(NMe₂)₃, SnMe₃(NMe₂), and the like.

In other embodiments, the non-limiting metal-containing precursor includes an organometallic agent having the formula (VIII):

MₐL_{c} (VIII),

in which M is a metal; L is a ligand, ion, or other moiety which is reactive with the counter-reactant; a≥1; and c≥1. In particular embodiments, c=n−1, and n is 2, 3, or 4. In some embodiments, M is Sn, Te, Bi, or Sb. Counter-reactants preferably have the ability to replace the reactive moieties ligands or ions (e.g., L in formulas herein) so as to link at least two metal atoms via chemical bonding.

In any embodiment herein, R can be an optionally substituted alkyl (e.g., C₁₋₁₀ alkyl). In one embodiment, alkyl is substituted with one or more halo (e.g., halo-substituted C₁₋₁₀ alkyl, including one, two, three, four, or more halo, such as F, Cl, Br, or I). Exemplary R substituents include CₙH₂ₙ₊₁, preferably wherein n≥3; and CₙFₓH₍₂ₙ₊₁₋ₓ₎, wherein 2n+1≤x≤1. In various embodiments, R has at least one beta-hydrogen or beta-fluorine. For example, R may be selected from the group consisting of i-propyl, n-propyl, t-butyl, i-butyl, n-butyl, sec-butyl, n-pentyl, i-pentyl, t-pentyl, sec-pentyl, and mixtures thereof.

In any embodiment herein, L may be any moiety readily displaced by a counter-reactant to generate an M-OH moiety, such as a moiety selected from the group consisting of an amino (e.g., —NR¹R², in which each of R¹ and R² can be H or alkyl, such as any described herein), alkoxy (e.g., —OR, in which R is alkyl, such as any described herein), carboxylates, halo (e.g., F, Cl, Br, or I), and mixtures thereof.

In particular embodiments, the metal precursor includes tin. In some embodiments, the tin precursor includes SnR or SnR₂ or SnR₄ or R₃SnSnR₃, wherein each R is, independently, H, halo, optionally substituted C₁₋₁₂ alkyl, optionally substituted C₁₋₁₂ alkoxy, optionally substituted amino (e.g., —NR¹R²), optionally substituted C₂₋₁₂ alkenyl, optionally substituted C₂-₁₂ alkynyl, optionally substituted C₃₋₈ cycloalkyl, optionally substituted aryl, cyclopentadienyl, optionally substituted bis(trialkylsilyl)amino (e.g., —N(SiR¹R²R³)₂), optionally substituted alkanoyloxy (e.g., acetate), a diketonate (e.g., —OC(R¹)-Ak-(R²)CO—), or a bidentate chelating dinitrogen (e.g., —N(R¹)-Ak-N(R¹)—). In particular embodiments, each R¹, R², and R³ is, independently, H or C₁₋₁₂ alkyl (e.g., methyl, ethyl, isopropyl, t-butyl, or neopentyl); and Ak is optionally substituted C₁₋₆ alkylene. Non-limiting tin precursors include SnF₂, SnH₄, SnBr₄, SnCl₄, SnI₄, tetramethyl tin (SnMe₄), tetraethyl tin (SnEt₄), trimethyl tin chloride (SnMe₃Cl), dimethyl tin dichloride (SnMe₂Cl₂), methyl tin trichloride (SnMeCl₃), tetraallyltin, tetravinyl tin, hexaphenyl ditin (IV) (Ph₃Sn—SnPh₃, in which Ph is phenyl), dibutyldiphenyltin (SnBu₂Ph₂), trimethyl(phenyl) tin (SnMe₃Ph), trimethyl(phenylethynyl) tin, tricyclohexyl tin hydride, tributyl tin hydride (SnBu₃H), dibutyltin diacetate (SnBu₂(CH₃COO)₂), tin(II) acetylacetonate (Sn(acac)₂), SnBu₃(OEt), SnBu₂(OMe)₂, SnBu₃(OMe), Sn(t-BuO)₄, Sn(n-Bu)(t-BuO)₃, tetrakis(dimethylamino)tin (Sn(NMe₂)₄), tetrakis(ethylmethylamino)tin (Sn(NMeEt)₄), tetrakis(diethylamino)tin(IV) (Sn(NEt₂)₄), (dimethylamino)trimethyl tin(IV) (Sn(Me)₃(NMe₂), Sn(i-Pr)(NMe₂)₃, Sn(n-Bu)(NMe₂)₃, Sn(s-Bu)(NMe₂)₃, Sn(i-Bu)(NMe₂)₃, Sn(t-Bu)(NMe₂)₃, Sn(t-Bu)₂(NMe₂)₂, Sn(t-Bu)(NEt₂)₃, Sn(tbba), Sn(II) (1,3-bis(1,1-dimethylethyl)-4,5-dimethyl-(4R,5R)-1,3,2-diazastannolidin-2-ylidene), or bis[bis(trimethylsilyl)amino]tin (Sn[N(SiMe₃)₂]₂).

Exemplary organometallic agents include SnMeCl₃, (N²,N³-di-t-butyl-butane-2,3-diamido) tin(II) (Sn(tbba)), bis(bis(trimethylsilyl)amido) tin(II), tetrakis(dimethylamino) tin(IV) (Sn(NMe₂)₄), t-butyl tris(dimethylamino) tin (Sn(t-butyl)(NMe₂)₃), i-butyl tris(dimethylamino) tin (Sn(i-Bu)(NMe₂)₃), n-butyl tris(dimethylamino) tin (Sn(n-Bu)(NMe₂)₃), sec-butyl tris(dimethylamino) tin (Sn(s-Bu)(NMe₂)₃), i-propyl(tris)dimethylamino tin (Sn(i-Pr)(NMe₂)₃), n-propyl tris(diethylamino) tin (Sn(n-Pr)(NEt₂)₃), and analogous alkyl(tris)(t-butoxy) tin compounds, such as t-butyl tris(t-butoxy) tin (Sn(t-Bu)(t-BuO)₃). In some embodiments, the organometallic agents are partially fluorinated.

### Film Composition

The patterning radiation-sensitive film can be formed by using one or more modified precursors, optionally in the presence of one or more counter-reactants. Furthermore, the modified precursor can be deposited (e.g., using any deposition process described herein), exposed, incubated, and optionally further processed (e.g., baked, treated, annealed, exposed to plasma, etc.) to provide a metal oxide layer (e.g., a layer including a network of metal oxide bonds, which may include other non-metal and non-oxygen groups).

The present disclosure encompasses a stack including: a semiconductor substrate having a top surface; and a patterning radiation-sensitive film disposed on the top surface of the semiconductor substrate. In some embodiments, the film includes a radiation-absorbing unit (e.g., a radiation-sensitive element) and a radiation-sensitive carbon-containing unit from an organic co-reactant (e.g., a radiation-responsive organic moiety, such as any described herein). In particular embodiments, the radiation-sensitive carbon-containing unit is a bound ligand formed as a reaction product between the radiation-absorbing unit (e.g., in an organometallic precursor) and the organic co-reactant. Non-limiting examples of radiation-absorbing units include a metal or a metalloid (e.g., tin (Sn), tellurium (Te), hafnium (Hf), and zirconium (Zr), or a combination thereof). In other embodiments, the radiation-sensitive carbon-containing unit is selected from the group of alkenylene moieties, alkynylene moieties, carbonyl moieties, and dicarbonyl moieties, or a combination thereof. The film can be exposed (to provide an exposed film) and then incubated (to provide an incubated film).

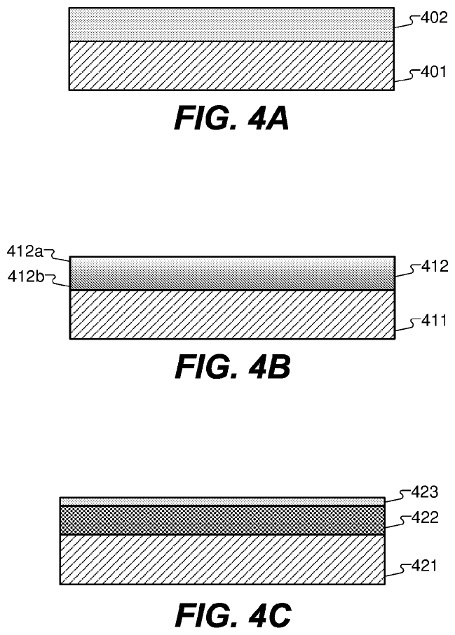

FIG. 4A provides an exemplary stack including a substrate 401 (e.g., a semiconductor substrate) having a top surface and a film 402 disposed on the top surface of the substrate 401. The film can include any useful patterning radiation-sensitive material (e.g., an EUV-sensitive material, such as any described herein, which can be useful as a PR). In some embodiments, the patterning radiation-sensitive film includes a modified precursor or a deposited from thereof. The deposited form can be an organometallic material, such as an organometal oxide (e.g., RM(MO)ₙ, in which M is a metal and R is an organic moiety having one or more carbon atoms, such as in alkyl, alkylamino, or alkoxy). The substrate can include any useful wafer, feature(s), layer(s), or device(s). In some embodiments, substrates are silicon wafers having any useful feature (e.g., irregular surface topography), layer (e.g., photoresist layer), or device.

The EUV-sensitive film can include a radiation-absorbing unit and a radiation-sensitive carbon-containing unit. In some embodiments, the radiation-absorbing unit includes or is an EUV-absorbing unit. Non-limiting examples of these include, e.g., a metal with a high EUV absorption cross-section, such as equal to or greater than 1×10⁷ cm²/mol. In other embodiments, the radiation-absorbing unit includes or is M (e.g., in which M can be Sn, Te, Bi, Sb, Hf, or Zr, or a combination thereof). In some embodiments, the radiation-sensitive carbon-containing unit is an EUV-sensitive carbon-containing unit. In particular embodiments, the EUV-sensitive carbon-containing unit includes an organic co-reactant or a reaction product thereof. Non-limiting examples of EUV-sensitive carbon-containing unit include, e.g., an organic moiety, such as any described herein (e.g., alkenylene moieties, alkynylene moieties, carbonyl moieties, dicarbonyl moieties, or combinations thereof).

In some embodiments, the EUV-sensitive film can be characterized by an increased or a decreased carbon content, such as an increase in metal-carbon or oxygen-carbon bonds or an increase in various organic moieties, such as alkenylene, alkylene, carbonyl, or dicarbonyl moieties (e.g., a substituted alkylene group having two carbonyl moieties). The presence or use of an organic co-reactant within a film can be detected in any useful manner. Non-limiting methods include, e.g., use of Fourier-transform infrared (FTIR) spectroscopy, solid state nuclear magnetic resonance (NMR) spectroscopy, and/or ultraviolet-visible (UV-Vis) spectroscopy to detect a functional group present within the organic co-reactant. This increase or decrease in organic carbon content can optionally enhance porosity of the film, as compared to a film formed without an organic co-reactant. Non-limiting methods to measure porosity include, e.g., volumetric gas adsorption.

In some embodiments, the EUV-sensitive film includes a vertical gradient characterized by a change in EUV absorbance. In particular embodiments, the vertical gradient includes an increase in EUV absorbance, in which a bottom portion of the film in proximity to the substrate has a higher EUV absorbance than a top portion of the film. In other embodiments, the vertical gradient includes a decrease in carbon content, in which a bottom portion of the film in proximity to the substrate has a lower carbon content than a top portion of the film. In yet other embodiments, the vertical gradient includes an increase in carbon content, in which a bottom portion of the film in proximity to the substrate has a higher carbon content than a top portion of the film.

The film can have a vertical gradient that is characterized by a vertical change in EUV absorbance (e.g., in which non-limiting methods and characteristics of gradient films are described herein). In some instances, an increase in EUV absorbance along a depth (e.g., going from a top surface of the film towards the substrate) can correspond with a decrease in carbon content along that same depth through the film layer. In other instances, an increase in EUV absorbance along a depth can correspond with an increase in tellurium, antimony, or iodine content along that same depth through the film layer.

FIG. 4B provides an exemplary stack including a substrate 411 (e.g., a semiconductor substrate) having a top surface and a film 412 disposed on the top surface of the substrate 411, in which the film 412 possesses a vertical gradient characterized by a change in EUV absorbance and/or carbon content. For instance, the gradient film 412 can include a first concentration of carbon content in a top portion 412a of the film and a second concentration of carbon content in a bottom portion 412b of the film, in which the first and second concentration values are different. In one instance, the first concentration is greater than the second concentration. In another instance, the first concentration is less than the second concentration. Non-limiting gradients include a linear gradient, an exponential gradient, a sigmoidal gradient, and the like. In particular embodiments, gradient density films of EUV-responsive organic moieties can yield more homogeneous film properties of EUV exposed areas at all depths in the film, which might improve development processes, improve EUV sensitivity, and/or improve patterning quality (e.g., having improved LWR and/or LER).

In some embodiments, the stack includes a photoresist layer having the radiation-absorbing unit and the radiation-sensitive carbon-containing unit. In other embodiments, the stack includes a capping layer (e.g., which can include a radiation-absorbing unit and a radiation-sensitive carbon-containing unit).

The patterning radiation-sensitive film (e.g., EUV-sensitive film) can be employed as a capping layer, which in turn is disposed on any useful layer or structure. As seen in FIG. 4C, the stack can include a substrate 421 (e.g., a semiconductor substrate) having a top surface, in which the substrate 421 further includes a photoresist layer 422. The EUV-sensitive film 423 is a capping layer disposed on a top surface of the photoresist layer 422. Such a capping layer can serve to reduce off gassing that can occur during EUV exposure of the underlying photoresist layer. This capping layer may also provide a barrier to chemical species evolved during the EUV patterning process. In particular, if the photoresist layer is formed from a metal-containing precursor (e.g., an organometallic agent, a metal halide, as well as any described herein), then the capping layer can trap evolving metal or chemical species produced during EUV exposure and, thus, minimize contamination of the lithography equipment. The capping layer can be any useful thickness (e.g., any thickness described herein, including from about 0.1 nm to about 5 nm, such as from about 0.1 nm to 0.5 nm, 0.1 nm to 1 nm, 0.1 nm to 3 nm, 0.3 nm to 0.5 nm, 0.3 nm to 1 nm, 0.3 nm to 3 nm, 0.3 nm to 5 nm, 0.5 nm to 1 nm, 0.5 nm to 3 nm, 0.5 nm to 5 nm, 0.8 nm to 1 nm, 0.8 nm to 3 nm, 0.8 nm to 5 nm, 1 nm to 3 nm, 1 nm to 5 nm, or 3 nm to 5 nm).

A capping layer can be provided in any useful manner. In one instance, the method includes providing a substrate including a photoresist layer and then depositing a modified precursor (e.g., formed in situ by providing an organometallic precursor in the presence of an organic co-reactant) on a surface of the photoresist layer. In this way, the capping layer is formed from the modified precursor and serves to protect the photoresist layer, which in turn can also include an EUV-sensitive material. The EUV-sensitive material in the capping and photoresist layers can possess different metal to carbon ratios, in which the capping layer 423 can have an increased carbon content, as compared to the photoresist layer 422. The capping layer may be present during patterning and, in some instances, reduce emission of volatile chemical and metal species from the photoresist layer during EUV exposure.

In particular embodiments, a different metal to carbon ratio can be achieved by using the same organometallic precursor and the same organic co-reactant in both the capping and photoresist layer, but the ratio of the organometallic precursor to the organic co-reactant can be modulated during deposition to provide a different metal to carbon ratio. In other embodiments, a different metal to carbon ratio can be achieved by using the same organometallic precursor but different organic co-reactant in the two layers. For instance, the capping layer can include use of a co-reactant having a bulkier organic substituent (e.g., ethyl, propyl, or butyl) than the organic substituent for the co-reactant of the photoresist layer (e.g., methyl).

The photoresist layer 422 can be provided in any useful manner. In one instance, the photoresist layer is provided by depositing an organometallic precursor (e.g., an organometallic agent, a metal halide, or any herein) optionally in the presence of a counter-reactant. In another instance, the photoresist layer is provided by depositing an organometallic precursor in the presence of an organic co-reactant. After producing the photoresist layer, a capping layer can be provided.

### Lithographic Processes

EUV lithography makes use of EUV resists, which may be polymer-based chemically amplified resists produced by liquid-based spin-on techniques or metal oxide-based resists produced by dry vapor-deposited techniques. Such EUV resists can include any EUV-sensitive film or material described herein. Lithographic methods can include patterning the resist, e.g., by exposure of the EUV resist with EUV radiation to form a photo pattern, followed by developing the pattern by removing a portion of the resist according to the photo pattern to form a mask.

It should also be understood that while the present disclosure relates to lithographic patterning techniques and materials exemplified by EUV lithography, it is also applicable to other next generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources, X-ray, which formally includes EUV at the lower energy range of the X-ray range, as well as e-beam, which can cover a wide energy range. Such methods include those where a substrate (e.g., optionally having exposed hydroxyl groups) is contacted with a metal-containing precursor (e.g., any described herein) to form a metal oxide (e.g., a layer including a network of metal oxide bonds, which may include other non-metal and non-oxygen groups) film as the imaging/photoresist (PR) layer on the surface of the substrate. The specific methods may depend on the particular materials and applications used in the semiconductor substrate and ultimate semiconducting device. Thus, the methods described in this application are merely exemplary of the methods and materials that may be used in present technology.

Directly photopatternable EUV resists may be composed of or contain metals and/or metal oxides mixed within organic components. The metals/metal oxides can enhance the EUV photon adsorption and generate secondary electrons and/or show increased etch selectivity to an underlying film stack and device layers. These resists can be developed using a wet (solvent) approach, a dry approach, or a combination thereof.

A wet approach can include using a wafer on a track, where it is exposed to developing solvent, dried, and baked. For wet development, such a process can be optimized to eliminate substrate delamination and interface failures. A dry approach can include use of vapor(s) to remove desired PR regions. For dry development, such a process can be optimized to enhance etch selectivity between unexposed and EUV exposed resist material, reduce PR corner rounding that can arise from longer exposures under etching gas, and decrease line CD variation in the following transfer etch step. Additional processes employed during lithography are described in detail below.

### Deposition Processes, Including Dry Deposition

As discussed above, the present disclosure provides methods for making imaging layers on semiconductor substrates, which may be patterned using EUV or other next generation lithographic techniques. Methods include those where polymerized organometallic materials are produced in a vapor and deposited on a substrate. In some embodiments, dry deposition can employ any useful metal-containing precursor (e.g., metal halides, capping agents, or organometallic agents described herein). In other embodiments, a spin-on formulation may be used. Deposition processes can include applying a EUV-sensitive material as a resist film and/or as a capping layer upon the resist film. Exemplary EUV-sensitive materials are described herein.

The present technology includes methods by which EUV-sensitive films are deposited on a substrate, such films being operable as resists for subsequent EUV lithography and processing. Furthermore, a secondary EUV-sensitive film can be deposited upon an underlying primary EUV-sensitive film. In one instance, the secondary film constitutes a capping layer, and the primary film constitutes the imaging layer.

Such EUV-sensitive films comprise materials which, upon exposure to EUV, undergo changes, such as the loss of bulky pendant ligands bonded to metal atoms in low density M-OH rich materials, allowing their crosslinking to denser M-O-M bonded metal oxide materials. In other embodiments, EUV exposure results in further cross-linking between ligands bonded to metal atoms, thereby providing denser M-L-M bonded organometallic materials, in which L is a ligand. In yet other embodiments, EUV exposure results in loss of ligands to provide M-OH materials that can be removed by positive tone developers.

Through EUV patterning, areas of the film are created that have altered physical or chemical properties relative to unexposed areas. These properties may be exploited in subsequent processing, such as to dissolve either unexposed or exposed areas or to selectively deposit materials on either the exposed or unexposed areas. In some embodiments, the unexposed film has a hydrophobic surface, and the exposed film has a hydrophilic surface (it being recognized that the hydrophilic properties of exposed and unexposed areas are relative to one another) under the conditions at which such subsequent processing is performed. For example, the removal of material may be performed by leveraging differences in chemical composition, density, and cross-linking of the film. Removal may be by wet processing and/or dry processing, as further described herein.

The thickness of the EUV-patternable film formed on the surface of the substrate may vary according to the surface characteristics, materials used, and processing conditions. In various embodiments, the film thickness may range from about 0.5-100 nm. Preferably, the film has a sufficient thickness to absorb most of the EUV light under the conditions of EUV patterning. For example, the overall absorption of the resist film may be 30% or less (e.g., 10% or less, or 5% or less), so that the resist material at the bottom of the resist film is sufficiently exposed. In some embodiments, the film thickness is from 10-20 nm. In some embodiments, the deposited films may closely conform to surface features, providing advantages in forming masks over substrates, such as substrates having underlying features, without “filling in” or otherwise planarizing such features.

The film (e.g., imaging layer) or capping layer may be composed of a metal oxide layer deposited in any useful manner. Such a metal oxide layer can be deposited or applied by using any EUV-sensitive material described herein, such as a metal-containing precursor (e.g., a metal halide, a capping agent, or an organometallic agent) in combination with an organic co-reactant. In exemplary processes, a polymerized organometallic material is formed in vapor phase or in situ on the surface of the substrate in order to provide the metal oxide layer. The metal oxide layer may be employed as a film, an adhesion layer, or a capping layer.

Optionally, the metal oxide layer can include a hydroxyl-terminated metal oxide layer, which can be deposited by employing a capping agent (e.g., any described herein) with an oxygen-containing counter-reactant. Such a hydroxyl-terminated metal oxide layer can be employed, e.g., as an adhesion layer between two other layers, such as between the substrate and the film and/or between the photoresist layer and the capping layer.

Exemplary deposition techniques (e.g., for a film or a capping layer) include any described herein, such as ALD (e.g., thermal ALD and plasma-enhanced ALD), spin-coat deposition, PVD including PVD co-sputtering, CVD (e.g., PE-CVD or LP-CVD), sputter deposition, e-beam deposition including e-beam co-evaporation, etc., or a combination thereof, such as ALD with a CVD component, such as a discontinuous, ALD-like process in which metal-containing precursors, organic co-reactants, and counter-reactants are separated in either time or space.

Further description of precursors and methods for their deposition as EUV photoresist films applicable to this disclosure may be found in International Appl. No. PCT/US19/31618, published as International Pub. No. WO 2019/217749, filed May 9, 2019, and titled METHODS FOR MAKING EUV PATTERNABLE HARD MASKS. The thin films may include optional materials in addition to an organometallic precursor, an organic co-reactant, and a counter-reactant to modify the chemical or physical properties of the film, such as to modify the sensitivity of the film to EUV or enhancing etch resistance. Such optional materials may be introduced, such as by doping during vapor phase formation prior to deposition on the substrate, after deposition of the film, or both. In some embodiments, a gentle remote H₂ plasma may be introduced so as to replace some Sn-L bonds with Sn—H, for example, which can increase reactivity of the resist under EUV.

In general, methods can include mixing a vapor stream of an organometallic precursor (e.g., a metal-containing precursor, such as an organometallic agent) with a vapor stream of an organic co-reactant and an optional vapor stream of a counter-reactant so as to form a polymerized organometallic material, and depositing the organometallic material onto the surface of the semiconductor substrate. In some embodiments, mixing the metal-containing precursor with the organic co-reactant and optional counter-reactant can form a polymerized organometallic material. As will be understood by one of ordinary skill in the art, the mixing and depositing aspects of the process may be concurrent, in a substantially continuous process.

In an exemplary continuous CVD process, two or more gas streams, in separate inlet paths, of sources of organometallic precursor, organic co-reactant, and optional counter-reactant are introduced to the deposition chamber of a CVD apparatus, where they mix and react in the gas phase, to form agglomerated polymeric materials (e.g., via metal-oxygen-metal bond formation) or a film on the substrate. Gas streams may be introduced, for example, using separate injection inlets or a dual-plenum showerhead. The apparatus is configured so that the streams of organometallic precursor, organic co-reactant, and optional counter-reactant are mixed in the chamber, allowing the organometallic precursor, organic co-reactant, and optional counter-reactant to react to form a polymerized organometallic material or a film (e.g., a metal oxide coating or agglomerated polymeric materials, such as via metal-oxygen-metal bond formation).

For depositing metal oxide, the CVD process is generally conducted at reduced pressures, such as from 0.1-10 Torr. In some embodiments, the process is conducted at pressures from 1-2 Torr. The temperature of the substrate is preferably below the temperature of the reactant streams. For example, the substrate temperature may be from 0-250° C., or from ambient temperature (e.g., 23° C.) to 150° C.

For depositing agglomerated polymeric materials, the CVD process is generally conducted at reduced pressures, such as from 10 mTorr to 10 Torr. In some embodiments, the process is conducted at from 0.5-2 Torr. The temperature of the substrate is preferably at or below the temperature of the reactant streams. For example, the substrate temperature may be from 0-250° C., or from ambient temperature (e.g., 23° C.) to 150° C. In various processes, deposition of the polymerized organometallic material on the substrate occurs at rates inversely proportional to surface temperature. Without limiting the mechanism, function or utility of present technology, it is believed that the product from such vapor-phase reaction becomes heavier in molecular weight as metal atoms are crosslinked by organic co-reactants and/or counter-reactants, and is then condensed or otherwise deposited onto the substrate. In various embodiments, the steric hindrance of the bulky alkyl groups (e.g., provided by the organic co-reactant) further prevents the formation of densely packed network and produces low density films having increased porosity.

A potential advantage of using dry deposition methods is ease of tuning the composition of the film as it grows. In a CVD process, this may be accomplished by changing the relative flows of the organometallic precursor and the organic co-reactant during deposition. Deposition may occur between 30-200° C. at pressures between 0.01-100 Torr, but more generally between about 0.1-10 Torr.

A film (e.g., a metal oxide coating or agglomerated polymeric materials, such as via metal-oxygen-metal bond formation) may also be deposited by an ALD process. For example, the organometallic precursor, organic co-reactant, and optional counter-reactant are introduced at separate times, representing an ALD cycle. The precursors and organic co-reactants react on the surface, forming up to a monolayer of material at a time for each cycle. This may allow for excellent control over the uniformity of film thickness across the surface. The ALD process is generally conducted at reduced pressures, such as from 0.1-10 Torr. In some embodiments, the process is conducted from 1-2 Torr. The substrate temperature may be from 0-250° C., or from ambient temperature (e.g., 23° C.) to 150° C. The process may be a thermal process or, preferably, a plasma-assisted deposition.

Any of the deposition methods herein can be modified to allow for use of two or more different organometallic precursors. In one embodiment, the precursors can include the same metal but different ligands. In another embodiment, the precursors can include different metal groups. In one non-limiting instance, alternating flows of various volatile metal-containing precursors can provide a mixed metal layer, such as use of a metal alkoxide precursor having a first metal (e.g., Sn) with a silyl-based precursor having a different second metal (e.g., Te).

Also, any of the deposition methods herein can be modified to allow for use of two or more different organic co-reactants. In one embodiment, the organic co-reactants can provide different bound ligands to the metal centers. In one non-limiting instance, alternating flows of various organic co-reactants can provide a layer with varying carbon content, such as in a gradient film.

Furthermore, any of the deposition methods herein can be modified to provide one or more layers within a film or a capping layer. In one instance, different organometallic precursors and/or organic co-reactants can be employed in each layer. In another instance, the same precursor may be employed for each layer, but the top-most layer can possess a different chemical composition (e.g., a different density of metal-ligand bonds, a different metal to carbon ratio, or a different bound ligand, as provided by modulating or changing the organic co-reactant).

Processes herein can be used to achieve a surface modification. In some iterations, a vapor of the organometallic precursor may be passed over the wafer. The wafer may be heated to provide thermal energy for the reaction to proceed. In some iterations, the heating can be between about 50° C.-250° C. In some cases, pulses of the organic co-reactant may be used, separated by pump and/or purging steps. For instance, an organic co-reactant may be pulsed between the precursor pulses resulting in ALD or ALD-like growth. In other cases, both the precursor and the organic co-reactant may be flowed at the same time. Examples of elements useful for surface modification include I, F, Sn, Bi, Sb, Te, and oxides or alloys of these compounds.

The processes herein can be used to deposit a thin metal oxide or metal by ALD or CVD. Examples include SnOx, BiOx, and Te. Following deposition, the film may be capped with an alkyl substituted precursor of the form MₐR_{b}L_{c}, as described elsewhere herein. A counter-reactant may be used to better remove the ligands, and multiple cycles may be repeated to ensure complete saturation of the substrate surface. The surface can then ready for the EUV-sensitive film to be deposited. One possible method is to produce a thin film of SnOx. Possible chemistries include growth of SnO₂ by cycling tetrakis(dimethylamino)tin and a counter-reactant such as water or O₂ plasma. After the growth, a capping agent could be used. For example, isopropyltris(dimethylamino)tin vapor may be flown over the surface.

Deposition processes can be employed on any useful surface. As referred to herein, the “surface” is a surface onto which a film of the present technology is to be deposited or that is to be exposed to EUV during processing. Such a surface can be present on a substrate (e.g., upon which a film is to be deposited), on a film (e.g., upon which a capping layer is to be deposited), or on a capping layer.

Any useful substrate can be employed, including any material construct suitable for lithographic processing, particularly for the production of integrated circuits and other semiconducting devices. In some embodiments, substrates are silicon wafers. Substrates may be silicon wafers upon which features have been created (“underlying topographical features”), having an irregular surface topography.

Such underlying topographical features may include regions in which material has been removed (e.g., by etching) or regions in which materials have been added (e.g., by deposition) during processing prior to conducting a method of this technology. Such prior processing may include methods of this technology or other processing methods in an iterative process by which two or more layers of features are formed on the substrate. In some embodiments, the film is configured to conform to underlying features without “filling in” or otherwise planarizing such features, thereby allowing such films to be deposited on a wide variety of material surfaces.

In some embodiments, an incoming wafer can be prepared with a substrate surface of a desired material, with the uppermost material being the layer into which the resist pattern is transferred. While the material selection may vary depending on integration, it is generally desired to select a material that can be etched with high selectivity to (i.e., much faster than) the EUV resist or imaging layer. Suitable substrate materials can include various carbon-based films (e.g., ashable hard mask (AHM)), silicon-based films (e.g., silicon, silicon oxide, silicon nitride, silicon oxynitride, or silicon oxycarbonitride, as well as doped forms thereof, including SiOₓ, SiOₓN_{y}, SiOₓC_{y}N_{z}, a-Si:H, poly-Si, or SiN), or any other (generally sacrificial) film applied to facilitate the patterning process.

In some embodiments, the substrate is a hard mask, which is used in lithographic etching of an underlying semiconductor material. The hard mask may comprise any of a variety of materials, including amorphous carbon (a-C), tin oxide (e.g., SnOx), silicon oxide (e.g., SiO₂), silicon oxynitride (e.g., SiOₓN_{y}), silicon oxycarbide (e.g., SiOₓC_{y}), silicon nitride (e.g., Si₃N₄), titanium oxide (e.g., TiO₂), titanium nitride (e.g., TiN), tungsten (e.g., W), doped carbon (e.g., W-doped C), tungsten oxide (e.g., WOₓ), hafnium oxide (e.g., HfO₂), zirconium oxide (e.g., ZrO₂), and aluminum oxide (e.g., Al₂O₃). For example, the substrate may preferably comprise SnOx, such as SnO₂. In various embodiments, the layer may be from 1-100 nm thick, or from 2-10 nm thick.

In some non-limiting embodiments, a substrate comprises an underlayer. An underlayer may be deposited on a hard mask or other layer and is generally underneath an imaging layer (or film), as described herein. An underlayer may be used to improve the sensitivity of a PR, increase EUV absorptivity, and/or increase the patterning performance of the PR. In cases where there are device features present on the substrate to be patterned which create significant topography, another important function of the underlayer can be to overcoat and planarize the existing topography so that the subsequent patterning step may be performed on a flat surface with all areas of the pattern in focus. For such applications, the underlayer (or at least one of multiple underlayers) may be applied using spin-coating techniques or dry deposition techniques. When the PR material being employed possesses a significant inorganic component, for example it exhibits a predominately metal oxide framework, the underlayer may advantageously be a carbon-based film, applied either by spin-coating or by dry vacuum-based deposition processes. The layer may include various ashable hard mask (AHM) films with carbon- and hydrogen-based compositions and may be doped with additional elements, such as tungsten, boron, nitrogen, or fluorine.

In some embodiments, a surface activation operation may be used to activate the surface (e.g., of the substrate and/or a film) for future operations. For example, for a SiOₓsurface, a water or oxygen/hydrogen plasma may be used to create hydroxyl groups on the surface. For a carbon- or hydrocarbon-based surface, various treatment (e.g., a water, hydrogen/oxygen, CO₂ plasma, or ozone treatment) may be used to create carboxylic acids/or hydroxyl groups. Such approaches can prove critical for improving the adhesion of resist features to the substrate, which might otherwise delaminate or lift off during handling or within the solvent during development.

Adhesion may also be enhanced by inducing roughness in the surface to increase the surface area available for interaction, as well as directly improve mechanical adhesion. For example, first a sputtering process using Ar or other non-reactive ion bombardment can be used to produce rough surfaces. Then, the surface can be terminated with a desired surface functionality as described above (e.g., hydroxyl and/or carboxylic acid groups). On carbon, a combination approach can be employed, in which a chemically reactive oxygen-containing plasma such as CO₂, O₂, or H₂O (or mixtures of H₂ and O₂) can be used to etch away a thin layer of film with local non-uniformity and simultaneously terminate with —OH, —OOH, or —COOH groups. This may be done with or without bias. In conjunction with the surface modification strategies mentioned above, this approach could serve the dual purpose of surface roughening and chemical activation of the substrate surface, either for direct adhesion to an inorganic metal-oxide based resist or as an intermediate surface modification for further functionalization.

In various embodiments, the surface (e.g., of the substrate and/or the film) comprises exposed hydroxyl groups on its surface. In general, the surface may be any surface that comprises, or has been treated to produce, an exposed hydroxyl surface. Such hydroxyl groups may be formed on the surface by surface treatment of a substrate using oxygen plasma, water plasma, or ozone. In other embodiments, the surface of the film can be treated to provide exposed hydroxyl groups, upon which a capping layer can be applied. In various embodiments, the hydroxyl-terminated metal oxide layer has a thickness of from 0.1-20 nm, or from 0.2-10 nm, or from 0.5-5 nm.

### EUV Exposure Processes

EUV exposure of the film can provide EUV exposed areas having activated reactive centers including a metal atom (M), which are produced by EUV-mediated cleavage events. Such reactive centers can include dangling metal bonds, M-H groups, cleaved M-ligand groups, dimerized M-M bonds, or M-O-M bridges. In other embodiments, EUV exposure provides cross-linked organic moieties by photopolymerizing ligands within the film; or EUV exposures releases gaseous by-products resulting from photolysis of bonds within a ligand.

EUV exposure can have a wavelength in the range of about 10-20 nm in a vacuum ambient, such as a wavelength of from 10-15 nm, e.g., 13.5 nm. In particular, patterning can provide EUV exposed areas and EUV unexposed areas to form a pattern.

The present technology can include patterning using EUV, as well as DUV or e-beam. In such patterning, the radiation is focused on one or more regions of the imaging layer. The exposure can be performed such that imaging layer film comprises one or more regions that are not exposed to the radiation. The resulting imaging layer may comprise a plurality of exposed and unexposed regions, creating a pattern consistent with the creation of transistor or other features of a semiconductor device, formed by addition or removal of material from the substrate in subsequent processing of the substrate. EUV, DUV and e-beam radiation methods and equipment among useful herein include methods and equipment known in the art.

In some EUV lithography techniques, an organic hardmask (e.g., an ashable hardmask of PECVD amorphous hydrogenated carbon) is patterned using a photoresist process. During photoresist exposure, EUV radiation is absorbed in the resist and in the substrate below, producing highly energetic photoelectrons (e.g., about 100 eV) and in turn a cascade of low-energy secondary electrons (e.g., about 10 eV) that diffuse laterally by several nanometers. These electrons increase the extent of chemical reactions in the resist which increases its EUV dose sensitivity. However, a secondary electron pattern that is random in nature is superimposed on the optical image. This unwanted secondary electron exposure results in loss of resolution, observable line edge roughness (LER) and linewidth variation in the patterned resist. These defects are replicated in the material to be patterned during subsequent pattern transfer etching.

A vacuum-integrated metal hardmask process and related vacuum-integrated hardware that combines film formation (deposition/condensation) and optical lithography with the result of greatly improved EUV lithography (EUVL) performance—e.g. reduced line edge roughness—is disclosed herein.

In various embodiments described herein, a deposition (e.g., condensation) process (e.g., ALD or MOCVD carried out in a PECVD tool, such as the Lam Vector®) can be used to form a thin film of a metal-containing film, such a photosensitive metal salt or metal-containing organic compound (organometallic compound), with a strong absorption in the EUV (e.g., at wavelengths on the order of 10-20 nm), for example at the wavelength of the EUVL light source (e.g., 13.5 nm=91.8 eV). This film photo-decomposes upon EUV exposure and forms a metal mask that is the pattern transfer layer during subsequent etching (e.g., in a conductor etch tool, such as the Lam 2300® Kiyo®).

Following deposition, the EUV-patternable thin film is patterned by exposure to a beam of EUV light, which can be performed under relatively high vacuum. For EUV exposure, the metal-containing film can then be deposited in a chamber integrated with a lithography platform (e.g., a wafer stepper such as the TWINSCAN NXE: 3300B® platform supplied by ASML of Veldhoven, NL) and transferred under vacuum so as not to react before exposure. Integration with the lithography tool is facilitated by the fact that EUVL also requires a greatly reduced pressure given the strong optical absorption of the incident photons by ambient gases such as H₂O, O₂, etc. In other embodiments, the photosensitive metal film deposition and EUV exposure may be conducted in the same chamber.

### Development Processes, Including Dry Development and Wet Development

EUV exposed or unexposed areas, as well as capping layers, can be removed by any useful development process. In one embodiment, the EUV exposed area can have activated reactive centers, such as dangling metal bonds, M-H groups, or dimerized M-M bonds. In particular embodiments, M-H groups can be selectively removed by employing one or more dry development processes (e.g., halide chemistry). In other embodiments, M-M bonds can be selectively removed by employing a wet development process, e.g., use of hot ethanol and water to provide soluble M(OH)ₙ groups. In yet other embodiments, EUV exposed areas are removed by use of wet development (e.g., by using a positive tone developer). In some embodiments, EUV unexposed areas are removed by use of dry development.

Dry development processes can include the use of various compounds in gaseous or vapor form. For instance, such processes can include gaseous water (H₂O), oxygen (O₂), a gaseous acid, a gaseous halide, or a combination thereof. Non-limiting gaseous acids include hydrochloric acid (HCl), hydrobromic acid (HBr), hydrofluoric acid (HF), sulfuric acid (H₂SO₄), nitric acid (HNO₃), trifluoroacetic acid, trifluoroacetic anhydride, and others. Non-limiting gaseous halides include tetrafluoromethane (CF₄), boron trichloride (BCl₃), HCl, HBr, and combinations thereof. Combinations can be employed, such as a combination of gaseous water with a gaseous acid or a combination of O₂ with a gaseous acid.

Dry development processes can also include use of halides, such as HCl— or HBr-based processes. While this disclosure is not limited to any particular theory or mechanism of operation, the approach is understood to leverage the chemical reactivity of the dry-deposited EUV photoresist films with the clean chemistry (e.g., HCl, HBr, and BCl₃) to form volatile products using vapors or plasma. The dry-deposited EUV photoresist films can be removed with etch rates of up to 1 nm/s. The quick removal of dry-deposited EUV photoresist films by these chemistries is applicable to chamber cleaning, backside clean, bevel clean, and PR developing. Although the films can be removed using vapors at various temperatures (e.g., HCl or HBr at a temperature greater than −10° C., or BCl₃ at a temperature greater than 80° C., for example), a plasma can also be used to further accelerate or enhance the reactivity.

Plasma processes include transformer coupled plasma (TCP), inductively coupled plasma (ICP) or capacitively coupled plasma (CCP), employing equipment and techniques among those known in the art. For example, a process may be conducted at a pressure of >0.5 mTorr (e.g., such as from 1-100 mTorr), at a power level of <1000 W (e.g., <500 W). Temperatures may be from 30-300° C. (e.g., 30-120° C.), at flow rate of 100 to 1000 standard cubic centimeters per minute (sccm), e.g., about 500 sccm, for from 1 to 3000 seconds (e.g., 10 seconds to 600 seconds).

Where the halide reactant flows are of hydrogen gas and halide gas, a remote plasma/UV radiation is used to generate radicals from the H₂ and Cl₂ and/or Br₂, and the hydrogen and halide radicals are flowed to the reaction chamber to contact the patterned EUV photoresist on the substrate layer of the wafer. Suitable plasma power may range from 100-500 W, with no bias. It should be understood that while these conditions are suitable for some processing reactors, e.g., a Kiyo etch tool available from Lam Research Corporation, Fremont, CA, a wider range of process conditions may be used according to the capabilities of the processing reactor.

In thermal development processes, the substrate is exposed to dry development chemistry (e.g., a Lewis Acid) in a vacuum chamber (e.g., oven). Suitable chambers can include a vacuum line, a dry development hydrogen halide chemistry gas (e.g., HBr, HCl) line, and heaters for temperature control. In some embodiments, the chamber interior can be coated with corrosion resistant films, such as organic polymers or inorganic coatings. One such coating is polytetrafluoroethylene ((PTFE), e.g., Teflon™). Such materials can be used in thermal processes of this disclosure without risk of removal by plasma exposure.

The process conditions for the dry development may be reactant flow of 100-500 sccm (e.g., 500 sccm HBr or HCl), temperature of −10-120° C. (e.g., −10° C.), pressure of 1-500 mTorr (e.g., 300 mTorr) with no plasma and for a time of about 10 sec to 1 min, dependent on the photoresist film and capping layer and their composition and properties.

In various embodiments, methods of the present disclosure combine all dry steps of film deposition, formation by vapor deposition, (EUV) lithographic photopatterning, and dry development. In such processes, a substrate may directly go to a dry development/etch chamber following photopatterning in an EUV scanner. Such processes may avoid material and productivity costs associated with a wet development. A dry process can also provide more tunability and give further CD control and/or scum removal.

In various embodiments, the EUV photoresist, containing some amount of metal, metal oxide and organic components, can be dry developed by a thermal, plasma (e.g., including possibly photoactivated plasma, such as lamp-heated or UV lamp heated), or a mixture of thermal and plasma methods while flowing a dry development gas including a compound of formula RxZy, where R=B, Al, Si, C, S, SO with x>0 and Z=C₁, H, Br, F, CH₄ and y>0. The dry development can result in a positive tone, in which the RxZy species selectively removes the exposed material, leaving behind the unexposed counterpart as a mask. In some embodiments, the exposed portions of organotin oxide-based photoresist films are removed by dry development in accordance with this disclosure. Positive tone dry development may be achieved by the selective dry development (removal) of EUV exposed regions exposed to flows comprising hydrogen halides or hydrogen and halides, including HCl and/or HBr without striking a plasma, or flows of H₂ and Cl₂ and/or Br₂ with a remote plasma or UV radiation generated from plasma to generate radicals.

Wet development methods can also be employed. In particular embodiments, such wet developments methods are used to remove EUV exposed regions to provide a positive tone photoresist or a negative tone resist. In some embodiments, wet development includes a neutral developer (e.g., a pH neutral developer, such as water) or a peroxide-containing developer (e.g., including hydrogen peroxide, H₂O₂). Exemplary, non-limiting wet development can include use of a base in an alkaline developer (e.g., an aqueous alkaline developer), such as those including ammonium, e.g., ammonium hydroxide (NH₄OH); ammonium-based ionic liquids, e.g., tetramethylammonium hydroxide (TMAH), tetraethylammonium hydroxide (TEAH), tetrapropylammonium hydroxide (TPAH), tetrabutylammonium hydroxide (TBAH), or other quatemary alkylammonium hydroxides; an organoamine, such as mono-, di-, and tri-organoamines (e.g., diethylamine, diethylamine, ethylenediamine, triethylenetetramine); or an alkanolamine, such as monoethanolamine, diethanolamine, triethanolamine, or diethyleneglycolamine. In other embodiments, the alkaline developer can include nitrogen-containing bases, e.g., compounds having the formula R^{N1}NH₂, R^{N1}R^{N2}NH, R^{N1}R^{N2}R^{N3}N, or R^{N1}R^{N2}R^{N3}R^{N4}N⁺X^{N1-}, where each of R^{N1}, R^{N2}, R^{N3}, and R^{N4} is, independently, an organo substituent (e.g., optionally substituted alkyl or any described herein), or two or more organo substituents that can be joined together, and X^{N1-} may comprise OH⁻, F⁻, Cl⁻, Br⁻, I⁻, or other art-known quaternary ammonium cationic species. These bases may also comprise heterocyclyl nitrogen compounds known in the art, some of which are described herein. Non-limiting combinations include water with a basic developer.

Other development methodologies can include use of an acid in an acidic developer (e.g., an aqueous acidic developer or an acid developer in an organic solvent) that includes a halide (e.g., HCl or HBr), an organic acid (e.g., formic acid, acetic acid, or citric acid), or an organofluorine compound (e.g., trifluoroacetic acid); or use of an organic developer, such as a ketone (e.g., 2-heptanone, cyclohexanone, or acetone), an ester (e.g., γ-butyrolactone or ethyl 3-ethoxypropionate (EEP)), an alcohol (e.g., isopropyl alcohol (IPA)), or an ether, such as a glycol ether (e.g., propylene glycol methyl ether (PGME) or propylene glycol methyl ether acetate (PGMEA)), as well as combinations thereof. Non-limiting combinations include water with an acidic developer.

In particular embodiments, the positive tone developer is an aqueous alkaline developer (e.g., including NH₄OH, TMAH, TEAH, TPAH, or TBAH). In other embodiments, the negative tone developer is an aqueous acidic developer, an acidic developer in an organic solvent, or an organic developer (e.g., HCl, HBr, formic acid, trifluoroacetic acid, 2-heptanone, IPA, PGME, PGMEA, or combinations thereof).

Any of the developers herein can include one or more surfactants. Surfactant can include a positive, negative, or neutral charge and may be selected from the group consisting of fluorinated or non-fluorinated surfactants. Non-limiting surfactants include quaternary ammonium salts, perfluorooctanoic acid ammonium salt, perfluorononanoic acid ammonium salt, fluorosurfactants, polyoxyethylene stearylether, polyoxyethylene oleyl ether, polyoxyethylene octylphenyl ether, polyoxyethylene nonylphenyl ether, polyethylene glycol dilaurate, polyethylene glycol distearate, alkylbenzene sulfonates, sodium sulfosuccinate, and sodium lauryl sulfate.

Wet development can include any useful process, including immersion development, puddle development, and spray development. After or during any of these processes, the substrate can be rotated to remove dissolved portions of the film while simultaneously drying the film.

The development process can include both wet and dry development processes. Such a process can include an initial wet development followed by a later dry development, or vice versa. Development can also occur in cycles, in which a plurality of wet development processes are used, a plurality of dry development processes are used, or a plurality of wet and dry development processes are employed. In one embodiment, the process can include a wet development process having liquid water, an aqueous solution, or an organic solvent (e.g., a ketone, such as any herein) in conjunction with a dry development process including gaseous water, oxygen (O₂), a gaseous acid, a gaseous halide, or a combination thereof.

### Post-Application Processes

The methods herein can include any useful post-application processes, as described below.

For the backside and bevel clean process, the vapor and/or the plasma can be limited to a specific region of the wafer to ensure that only the backside and the bevel are removed, without any film degradation on the frontside of the wafer. The deposited EUV photoresist films being removed are generally composed of Sn, 0 and C, but the same clean approaches can be extended to films of other metal oxide resists and materials. In addition, this approach can also be used for film strip and PR rework.

Suitable process conditions for a dry bevel edge and backside clean may be a reactant flow of 100-500 sccm (e.g., 500 sccm HCl, HBr, or H₂ and Cl₂ or Br₂, BCl₃ or H₂), temperature of −10-120° C. (e.g., 20° C.), pressure of 20-500 mTorr (e.g., 300 mTorr), plasma power of 0-500 W at high frequency (e.g., 13.56 MHz), and for a time of about 10-20 sec, dependent on the photoresist film and composition and properties. It should be understood that while these conditions are suitable for some processing reactors, e.g., a Kiyo etch tool available from Lam Research Corporation, Fremont, CA, a wider range of process conditions may be used according to the capabilities of the processing reactor.

Photolithography processes can involve one or more bake steps, to facilitate the chemical reactions required to produce chemical contrast between exposed and unexposed areas of the photoresist. For high volume manufacturing (HVM), such bake steps can be performed on tracks where the wafers are baked on a hot-plate at a pre-set temperature under ambient air or in some cases N₂ flow. More careful control of the bake ambient as well as introduction of additional reactive gas component in the ambient during these bake steps can help further reduce the dose requirement and/or improve pattern fidelity.

According to various aspects of this disclosure, one or more post treatments to metal and/or metal oxide-based photoresists after deposition (e.g., post-application bake (PAB)) and/or exposure (e.g., post-exposure bake (PEB)) and/or development (e.g., post-development bake (PDB)) are capable of increasing material property differences between exposed and unexposed photoresist and therefore decreasing dose to size (DtS), improving PR profile, and improving line edge and width roughness (LER/LWR) after subsequent dry development. Such processing can involve a thermal process with the control of temperature, gas ambient, and moisture, resulting in improved dry development performance in processing to follow. In some instances, a remote plasma might be used.

In the case of post-application processing (e.g., PAB), a thermal process with control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum, and moisture can be used after deposition and before exposure to change the composition of unexposed metal and/or metal oxide photoresist. The change can increase the EUV sensitivity of the material and thus lower dose to size and edge roughness can be achieved after exposure and dry development.

In the case of post-exposure processing (e.g., incubating or PEB), a thermal process with the control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum, and moisture can be used to change the composition of both unexposed and exposed photoresist. The change can increase the composition/material properties difference between the unexposed and exposed photoresist and the etch rate difference of dry development etch gas between the unexposed and exposed photoresist. A higher etch selectivity can thereby be achieved. Due to the improved selectivity, a squarer PR profile can be obtained with improved surface roughness, and/or less photoresist residual/scum. In particular embodiments, PEB can be performed in air and in the optional presence of moisture and CO₂.

In the case of post-development processing (e.g., post development bake or PDB), a thermal process with the control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum (e.g., with UV), and moisture can be used to change the composition of the unexposed photoresist. In particular embodiments, the condition also includes use of plasma (e.g., including O₂, O₃, Ar, He, or their mixtures). The change can increase the hardness of material, which can be beneficial if the film will be used as a resist mask when etching the underlying substrate.

In these cases, in alternative implementations, the thermal process could be replaced by a remote plasma process to increase reactive species to lower the energy barrier for the reaction and increase productivity. Remote plasma can generate more reactive radicals and therefore lower the reaction temperature/time for the treatment, leading to increased productivity.

Accordingly, one or multiple processes may be applied to modify the photoresist itself to increase development selectivity. This thermal or radical modification can increase the contrast between unexposed and exposed material and thus increase the selectivity of the subsequent dry development step. The resulting difference between the material properties of unexposed and exposed material can be tuned by adjusting process conditions including temperature, gas flow, moisture, pressure, and/or RF power. The large process latitude enabled by dry development, which is not limited by material solubility in a wet developer solvent, allows more aggressive conditions to be applied further enhancing the material contrast that can be achieved. The resulting high material contrast feeds back a wider process window for dry development and thus enables increased productivity, lower cost, and better defectivity performance.

During wet development, the extent and number of temperature bakes can be optimized to provide desired development selectivity. For instance, as wet development can rely on material solubility, heating to or beyond 220° C., for example, can greatly increase the degree of cross-linking in both exposed and unexposed regions of a metal-containing PR film such that both become insoluble in the wet development solvents, so that the film can no longer by reliably wet developed. For dry-developed resist films, in which the etch rate difference (i.e., selectivity) between the exposed and unexposed regions of the PR is relied upon for removal of just the exposed or unexposed portion of the resist, the treatment temperature in a PAB, PEB, or PDB can be varied across a much broader window to tune and optimize the treatment process, for example from about 90-250° C., such as 90-190° C., for PAB, and about 170-250° C. or more, such as 190-240° C., for PEB and/or PDB. Decreasing etch rate and greater etch selectivity has been found to occur with higher treatment temperatures in the noted ranges.

In particular embodiments, the PAB, PEB, and/or PDB treatments may be conducted with gas ambient flow in the range of 100-10000 sccm, moisture content in the amount of a few percent up to 100% (e.g., 20-50%), at a pressure between atmospheric and vacuum, and for a duration of about 1-15 minutes, for example about 2 minutes.

These findings can be used to tune the treatment conditions to tailor or optimize processing for particular materials and circumstances. For example, the selectivity achieved for a given EUV dose with a 220-250° C. PEB thermal treatment in air at about 20% humidity for about 2 minutes can be made similar to that for about a 30% higher EUV dose with no such thermal treatment. So, depending on the selectivity requirements/constraints of the semiconductor processing operation, a thermal treatment such as described herein can be used to lower the EUV dose needed. Or, if higher selectivity is required and higher dose can be tolerated, much higher selectivity, up to 100 times exposed vs. unexposed, can be obtained.

Yet other steps can include in situ metrology, in which physical and structural characteristics (e.g., critical dimension, film thickness, etc.) can be assessed during the photolithography process. Modules to implement in situ metrology include, e.g., scatterometry, ellipsometry, downstream mass spectroscopy, and/or plasma enhanced downstream optical emission spectroscopy modules.

### Apparatuses

The present disclosure also includes any apparatus configured to perform any methods described herein. In one embodiment, the apparatus for depositing a film includes a deposition module comprising a chamber for depositing an EUV-sensitive material as a film by providing an organometallic precursor in the presence of an organic co-reactant; a patterning module comprising an EUV photolithography tool with a source of sub-30 nm wavelength radiation; and a development module comprising a chamber for developing the film.

The apparatus can further include a controller having instructions for such modules. In one embodiment, the controller includes one or more memory devices, one or more processors, and system control software coded with instructions for conducting deposition of the film or the capping layer. Such includes can include for, in the deposition module, depositing a modified precursor as a film on a top surface of a substrate or a photoresist layer; in the patterning module, patterning the film with sub-30 nm resolution directly by EUV exposure, thereby forming a pattern within the film; and in the development module, developing the film. In particular embodiments, the development module provides for removal of the EUV exposed or EUV unexposed areas, thereby providing a pattern within the film.

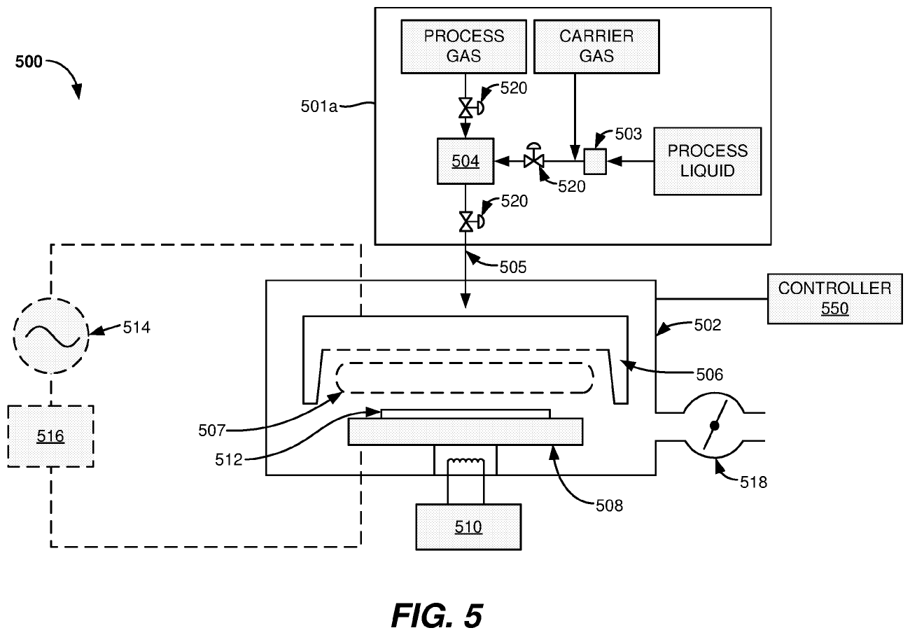

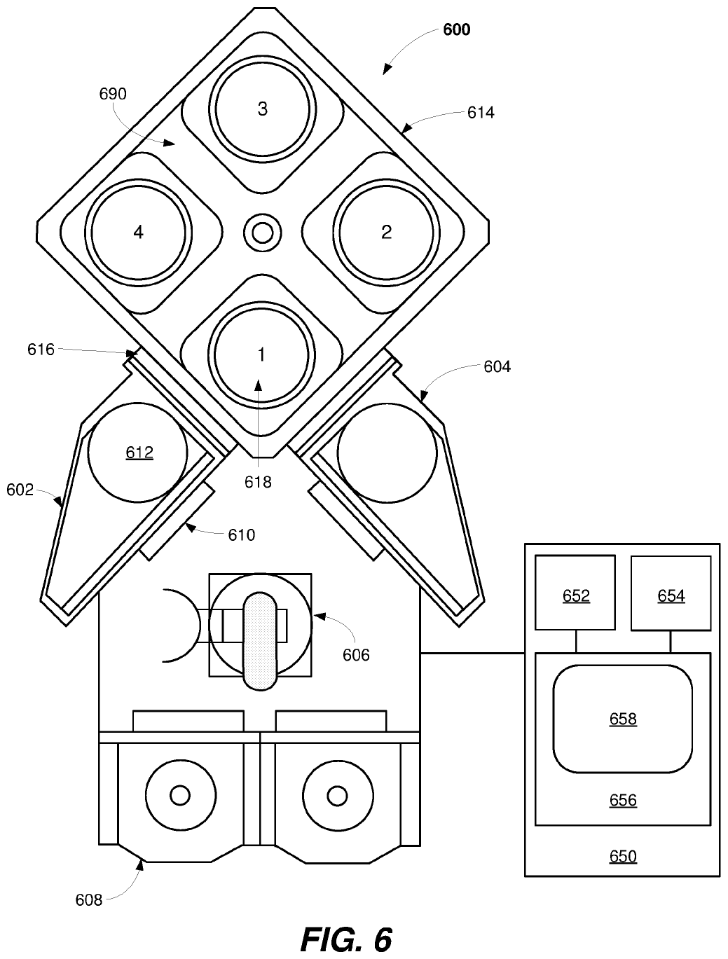

FIG. 5 depicts a schematic illustration of an embodiment of process station 500 having a process chamber body 502 for maintaining a low pressure environment that is suitable for implementation of described dry stripping and development embodiments. A plurality of process stations 500 may be included in a common low pressure process tool environment. For example, FIG. 6 depicts an embodiment of a multi-station processing tool 600, such as a VECTOR® processing tool available from Lam Research Corporation, Fremont, CA. In some embodiments, one or more hardware parameters of the process station 500 including those discussed in detail below may be adjusted programmatically by one or more computer controllers 550.

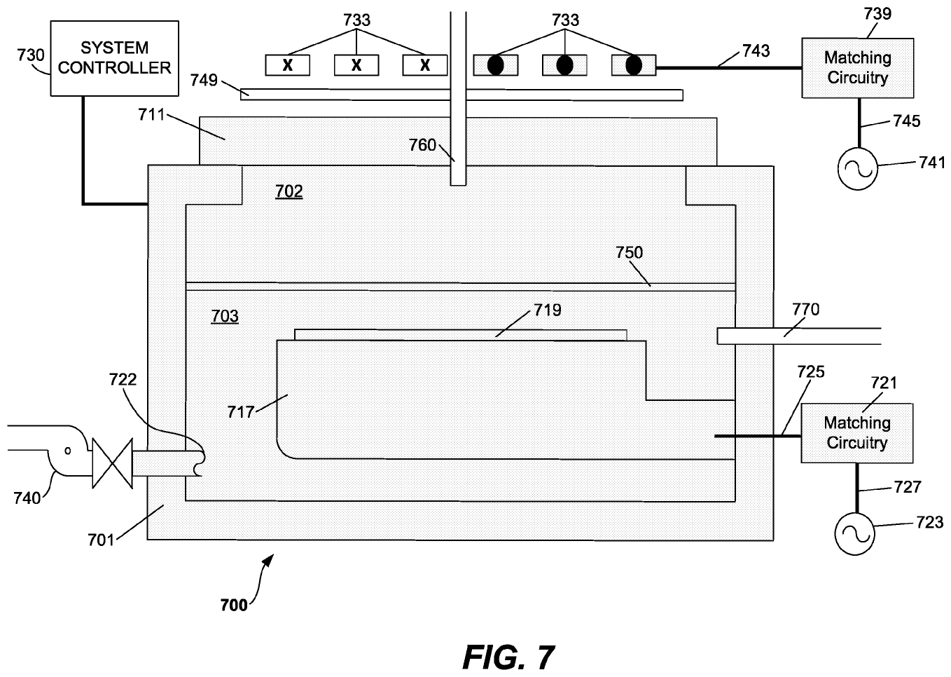

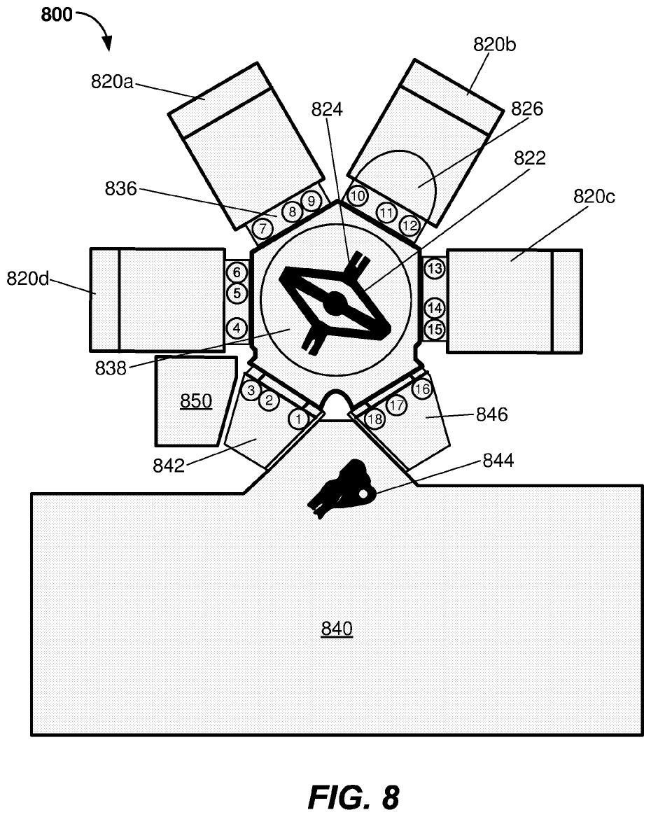

A process station may be configured as a module in a cluster tool. FIG. 8 depicts a semiconductor process cluster tool architecture with vacuum-integrated deposition and patterning modules suitable for implementation of the embodiments described herein. Such a cluster process tool architecture can include resist deposition, resist exposure (EUV scanner), resist dry development, and etch modules, as described herein with reference to FIG. 5 and FIG. 7.

In some embodiments, certain of the processing functions can be performed consecutively in the same module, for example dry development and etch. And embodiments of this disclosure are directed to methods and apparatus for receiving a wafer, including a photopatterned EUV resist thin film layer disposed on a layer or layer stack to be etched, to a dry development/etch chamber following photopatterning in an EUV scanner; dry developing photopatterned EUV resist thin film layer; and then etching the underlying layer using the patterned EUV resist as a mask, as described herein.

Returning to FIG. 5, process station 500 fluidly communicates with reactant delivery system 501a for delivering process gases to a distribution showerhead 506 by a connection 505. Reactant delivery system 501a optionally includes a mixing vessel 504 for blending and/or conditioning process gases, for delivery to showerhead 506. One or more mixing vessel inlet valves 520 may control introduction of process gases to mixing vessel 504. Where plasma exposure is used, plasma may also be delivered to the showerhead 506 or may be generated in the process station 500. Process gases can include, e.g., any described herein, such as an organic co-reactant, an organometallic precursor, or a counter-reactant.

FIG. 5 includes an optional vaporization point 503 for vaporizing liquid reactant to be supplied to the mixing vessel 504. The liquid reactant can include an organic co-reactant, an organometallic precursor, or a counter-reactant. In some embodiments, a liquid flow controller (LFC) upstream of vaporization point 503 may be provided for controlling a mass flow of liquid for vaporization and delivery to process station 500. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM.

Showerhead 506 distributes process gases toward substrate 512. In the embodiment shown in FIG. 5, the substrate 512 is located beneath showerhead 506 and is shown resting on a pedestal 508. Showerhead 506 may have any suitable shape and may have any suitable number and arrangement of ports for distributing process gases to substrate 512.

In some embodiments, pedestal 508 may be raised or lowered to expose substrate 512 to a volume between the substrate 512 and the showerhead 506. It will be appreciated that, in some embodiments, pedestal height may be adjusted programmatically by a suitable computer controller 550.

In some embodiments, pedestal 508 may be temperature controlled via heater 510. In some embodiments, the pedestal 508 may be heated to a temperature of greater than 0° C. and up to 300° C. or more, for example 50-120° C., such as about 65-80° C., during non-plasma thermal exposure of a photopatterned resist to dry development chemistry, such as HBr, HCl, or BCl₃, as described in disclosed embodiments.

Further, in some embodiments, pressure control for process station 500 may be provided by a butterfly valve 518. As shown in the embodiment of FIG. 5, butterfly valve 518 throttles a vacuum provided by a downstream vacuum pump (not shown). However, in some embodiments, pressure control of process station 500 may also be adjusted by varying a flow rate of one or more gases introduced to the process station 500.

In some embodiments, a position of showerhead 506 may be adjusted relative to pedestal 508 to vary a volume between the substrate 512 and the showerhead 506. Further, it will be appreciated that a vertical position of pedestal 508 and/or showerhead 506 may be varied by any suitable mechanism within the scope of the present disclosure. In some embodiments, pedestal 508 may include a rotational axis for rotating an orientation of substrate 512. It will be appreciated that, in some embodiments, one or more of these example adjustments may be performed programmatically by one or more suitable computer controllers 550.

Where plasma may be used, for example in gentle plasma-based dry development embodiments and/or etch operations conducted in the same chamber, showerhead 506 and pedestal 508 electrically communicate with a radio frequency (RF) power supply 514 and matching network 516 for powering a plasma 507. In some embodiments, the plasma energy may be controlled by controlling one or more of a process station pressure, a gas concentration, an RF source power, an RF source frequency, and a plasma power pulse timing. For example, RF power supply 514 and matching network 516 may be operated at any suitable power to form a plasma having a desired composition of radical species. Examples of suitable powers are up to about 500 W.

In some embodiments, instructions for a controller 550 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a recipe phase may include instructions for setting a flow rate of a dry development chemistry reactant gas, such as HBr or HCl, and time delay instructions for the recipe phase. In some embodiments, the controller 550 may include any of the features described below with respect to system controller 650 of FIG. 6.

As described above, one or more process stations may be included in a multi station processing tool. FIG. 6 shows a schematic view of an embodiment of a multi station processing tool 600 with an inbound load lock 602 and an outbound load lock 604, either or both of which may include a remote plasma source. A robot 606 at atmospheric pressure is configured to move wafers from a cassette loaded through a pod 608 into inbound load lock 602 via an atmospheric port 610. A wafer is placed by the robot 606 on a pedestal 612 in the inbound load lock 602, the atmospheric port 610 is closed, and the load lock is pumped down. Where the inbound load lock 602 includes a remote plasma source, the wafer may be exposed to a remote plasma treatment to treat the silicon nitride surface in the load lock prior to being introduced into a processing chamber 614. Further, the wafer also may be heated in the inbound load lock 602 as well, for example, to remove moisture and adsorbed gases. Next, a chamber transport port 616 to processing chamber 614 is opened, and another robot (not shown) places the wafer into the reactor on a pedestal of a first station shown in the reactor for processing. While the embodiment depicted in FIG. 6 includes load locks, it will be appreciated that, in some embodiments, direct entry of a wafer into a process station may be provided.

The depicted processing chamber 614 includes four process stations, numbered from 1 to 4 in the embodiment shown in FIG. 6. Each station has a heated pedestal (shown at 618 for station 1), and gas line inlets. It will be appreciated that in some embodiments, each process station may have different or multiple purposes. For example, in some embodiments, a process station may be switchable between dry development and etch process modes. Additionally or alternatively, in some embodiments, processing chamber 614 may include one or more matched pairs of dry development and etch process stations. While the depicted processing chamber 614 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 6 depicts an embodiment of a wafer handling system 690 for transferring wafers within processing chamber 614. In some embodiments, wafer handling system 690 may transfer wafers between various process stations and/or between a process station and a load lock. It will be appreciated that any suitable wafer handling system may be employed. Non limiting examples include wafer carousels and wafer handling robots. FIG. 6 also depicts an embodiment of a system controller 650 employed to control process conditions and hardware states of process tool 600. System controller 650 may include one or more memory devices 656, one or more mass storage devices 654, and one or more processors 652. Processor 652 may include a CPU or computer, analog, and/or digital input/output connections, stepper motor controller boards, etc.

In some embodiments, system controller 650 controls all of the activities of process tool 600. System controller 650 executes system control software 658 stored in mass storage device 654, loaded into memory device 656, and executed on processor 652. Alternatively, the control logic may be hard coded in the controller 650. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 658 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 600. System control software 658 may be configured in any suitable way. For example, various process tool component subroutines or control objects may be written to control operation of the process tool components used to carry out various process tool processes. System control software 658 may be coded in any suitable computer readable programming language.

In some embodiments, system control software 658 may include input/output control (IOC) sequencing instructions for controlling the various parameters described above. Other computer software and/or programs stored on mass storage device 654 and/or memory device 656 associated with system controller 650 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 618 and to control the spacing between the substrate and other parts of process tool 600.

A process gas control program may include code for controlling various gas compositions (e.g., HBr or HCl gas as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 650. The user interface may include a display screen, graphical software displays of the apparatus and/or process conditions, and user input devices such as pointing devices, keyboards, touch screens, microphones, etc.

In some embodiments, parameters adjusted by system controller 650 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 650 from various process tool sensors. The signals for controlling the process may be output on the analog and digital output connections of process tool 600. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 650 may provide program instructions for implementing the above-described deposition processes. The program instructions may control a variety of process parameters, such as DC power level, RF bias power level, pressure, temperature, etc. The instructions may control the parameters to operate dry development and/or etch processes according to various embodiments described herein.

The system controller 650 can include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 650.

In some implementations, the system controller 650 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 650, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 650 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 650 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 650, in some implementations, may be a part of or coupled to a computer that is integrated with, coupled to the system, otherwise networked to the system, or a combination thereof. For example, the system controller 650 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 650 receives instructions in the form of data, which specify parameters for each of the processing steps to be performed during one or more operations. It should be understood that the parameters may be specific to the type of process to be performed and the type of tool that the system controller 650 is configured to interface with or control. Thus, as described above, the system controller 650 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the system controller 650 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Inductively coupled plasma (ICP) reactors which, in certain embodiments, may be suitable for etch operations suitable for implementation of some embodiments, are now described. Although ICP reactors are described herein, in some embodiments, it should be understood that capacitively coupled plasma reactors may also be used.

FIG. 7 schematically shows a cross-sectional view of an inductively coupled plasma apparatus 700 appropriate for implementing certain embodiments or aspects of embodiments such as dry development and/or etch, an example of which is a Kiyo® reactor, produced by Lam Research Corp. of Fremont, CA. In other embodiments, other tools or tool types having the functionality to conduct the dry development and/or etch processes described herein may be used for implementation.

The inductively coupled plasma apparatus 700 includes an overall process chamber structurally defined by chamber walls 701 and a window 711. The chamber walls 701 may be fabricated from stainless steel or aluminum. The window 711 may be fabricated from quartz or other dielectric material. An optional internal plasma grid 750 divides the overall process chamber into an upper sub-chamber 702 and a lower sub-chamber 703. In most embodiments, plasma grid 750 may be removed, thereby utilizing a chamber space made of sub-chambers 702 and 703. A chuck 717 is positioned within the lower sub-chamber 703 near the bottom inner surface. The chuck 717 is configured to receive and hold a semiconductor wafer 719 upon which the etching and deposition processes are performed. The chuck 717 can be an electrostatic chuck for supporting the wafer 719 when present. In some embodiments, an edge ring (not shown) surrounds the chuck 717 and has an upper surface that is approximately planar with a top surface of the wafer 719, when present over the chuck 717. The chuck 717 also includes electrostatic electrodes for chucking and dechucking the wafer 719. A filter and DC clamp power supply (not shown) may be provided for this purpose.

Other control systems for lifting the wafer 719 off the chuck 717 can also be provided. The chuck 717 can be electrically charged using an RF power supply 723. The RF power supply 723 is connected to matching circuitry 721 through a connection 727. The matching circuitry 721 is connected to the chuck 717 through a connection 725. In this manner, the RF power supply 723 is connected to the chuck 717. In various embodiments, a bias power of the electrostatic chuck may be set at about 50 V or may be set at a different bias power depending on the process performed in accordance with disclosed embodiments. For example, the bias power may be between about 20 V and about 100 V, or between about 30 V and about 150 V.

Elements for plasma generation include a coil 733 positioned above window 711. In some embodiments, a coil is not used in disclosed embodiments. The coil 733 is fabricated from an electrically conductive material and includes at least one complete turn. The example of a coil 733 shown in FIG. 7 includes three turns. The cross sections of coil 733 are shown with symbols, and coils having an “X” extend rotationally into the page, while coils having a “•” extend rotationally out of the page. Elements for plasma generation also include an RF power supply 741 configured to supply RF power to the coil 733. In general, the RF power supply 741 is connected to matching circuitry 739 through a connection 745. The matching circuitry 739 is connected to the coil 733 through a connection 743. In this manner, the RF power supply 741 is connected to the coil 733. An optional Faraday shield 749 is positioned between the coil 733 and the window 711. The Faraday shield 749 may be maintained in a spaced apart relationship relative to the coil 733. In some embodiments, the Faraday shield 749 is disposed immediately above the window 711. In some embodiments, a Faraday shield is between the window 711 and the chuck 717. In some embodiments, the Faraday shield is not maintained in a spaced apart relationship relative to the coil 733. For example, a Faraday shield may be directly below the window without a gap. The coil 733, the Faraday shield 749, and the window 711 are each configured to be substantially parallel to one another. The Faraday shield 749 may prevent metal or other species from depositing on the window 711 of the process chamber.

Process gases may be flowed into the process chamber through one or more main gas flow inlets 760 positioned in the upper sub-chamber 702 and/or through one or more side gas flow inlets 770. Likewise, though not explicitly shown, similar gas flow inlets may be used to supply process gases to a capacitively coupled plasma processing chamber. A vacuum pump, e.g., a one or two stage mechanical dry pump and/or turbomolecular pump 740, may be used to draw process gases out of the process chamber and to maintain a pressure within the process chamber. For example, the vacuum pump may be used to evacuate the lower sub-chamber 703 during a purge operation of ALD. A valve-controlled conduit may be used to fluidically connect the vacuum pump to the process chamber so as to selectively control application of the vacuum environment provided by the vacuum pump. This may be done employing a closed loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus 700, one or more process gases may be supplied through the gas flow inlets 760 and/or 770. In certain embodiments, process gas may be supplied only through the main gas flow inlet 760, or only through the side gas flow inlet 770. In some cases, the gas flow inlets shown in the figure may be replaced by more complex gas flow inlets, one or more showerheads, for example. The Faraday shield 749 and/or optional grid 750 may include internal channels and holes that allow delivery of process gases to the process chamber. Either or both of Faraday shield 749 and optional grid 750 may serve as a showerhead for delivery of process gases. In some embodiments, a liquid vaporization and delivery system may be situated upstream of the process chamber, such that once a liquid reactant or precursor is vaporized, the vaporized reactant or precursor is introduced into the process chamber via a gas flow inlet 760 and/or 770.

Radio frequency power is supplied from the RF power supply 741 to the coil 733 to cause an RF current to flow through the coil 733. The RF current flowing through the coil 733 generates an electromagnetic field about the coil 733. The electromagnetic field generates an inductive current within the upper sub-chamber 702. The physical and chemical interactions of various generated ions and radicals with the wafer 719 etch features of and selectively deposit layers on the wafer 719.

If the plasma grid 750 is used such that there is both an upper sub-chamber 702 and a lower sub-chamber 703, the inductive current acts on the gas present in the upper sub-chamber 702 to generate an electron-ion plasma in the upper sub-chamber 702. The optional internal plasma grid 750 limits the amount of hot electrons in the lower sub-chamber 703. In some embodiments, the apparatus 700 is designed and operated such that the plasma present in the lower sub-chamber 703 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower sub-chamber 703 through port 722. The chuck 717 disclosed herein may operate at elevated temperatures ranging between about 10-250° C. The temperature will depend on the process operation and specific recipe.

Apparatus 700 may be coupled to facilities (not shown) when installed in a clean room or a fabrication facility. Facilities include plumbing that provide processing gases, vacuum, temperature control, and environmental particle control. These facilities are coupled to apparatus 700, when installed in the target fabrication facility. Additionally, apparatus 700 may be coupled to a transfer chamber that allows robotics to transfer semiconductor wafers into and out of apparatus 700 using automation.

In some embodiments, a system controller 730 (which may include one or more physical or logical controllers) controls some or all of the operations of a process chamber. The system controller 730 may include one or more memory devices and one or more processors. In some embodiments, the apparatus 700 includes a switching system for controlling flow rates and durations when disclosed embodiments are performed. In some embodiments, the apparatus 700 may have a switching time of up to about 600 ms, or up to about 750 ms. Switching time may depend on the flow chemistry, recipe chosen, reactor architecture, and other factors.

In some implementations, the system controller 730 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 730, which may control various components or subparts of the system or systems. The system controller, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 730 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller 730, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 730 receives instructions in the form of data, which specify parameters for each of the processing steps to be performed during one or more operations. It should be understood that the parameters may be specific to the type of process to be performed and the type of tool that the controller is configured to interface with or control. Thus, as described above, the system controller 730 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an ALE chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

EUVL patterning may be conducted using any suitable tool, often referred to as a scanner, for example the TWINSCAN NXE: 3300B® platform supplied by ASML of Veldhoven, NL. The EUVL patterning tool may be a standalone device from which the substrate is moved into and out of for deposition and etching as described herein. Or, as described below, the EUVL patterning tool may be a module on a larger multi-component tool. FIG. 8 depicts a semiconductor process cluster tool architecture with vacuum-integrated deposition, EUV patterning and dry development/etch modules that interface with a vacuum transfer module, suitable for implementation of the processes described herein. While the processes may be conducted without such vacuum integrated apparatus, such apparatus may be advantageous in some implementations.

FIG. 8 depicts a semiconductor process cluster tool architecture with vacuum-integrated deposition and patterning modules that interface with a vacuum transfer module, suitable for implementation of processes described herein. The arrangement of transfer modules to “transfer” wafers among multiple storage facilities and processing modules may be referred to as a “cluster tool architecture” system. Deposition and patterning modules are vacuum-integrated, in accordance with the requirements of a particular process. Other modules, such as for etch, may also be included on the cluster.

A vacuum transport module (VTM) 838 interfaces with four processing modules 820a-820d, which may be individually optimized to perform various fabrication processes. By way of example, processing modules 820a-820d may be implemented to perform deposition, evaporation, ELD, dry development, etch, strip, and/or other semiconductor processes. For example, module 820a may be an ALD reactor that may be operated to perform in a non-plasma, thermal atomic layer depositions as described herein, such as a Vector tool, available from Lam Research Corporation, Fremont, CA. And module 820b may be a PECVD tool, such as the Lam Vector®. It should be understood that the figure is not necessarily drawn to scale.

Airlocks 842 and 846, also known as a loadlocks or transfer modules, interface with the VTM 838 and a patterning module 840. For example, as noted above, a suitable patterning module may be the TWINSCAN NXE: 3300B® platform supplied by ASML of Veldhoven, NL. This tool architecture allows for work pieces, such as semiconductor substrates or wafers, to be transferred under vacuum so as not to react before exposure. Integration of the deposition modules with the lithography tool is facilitated by the fact that EUVL also requires a greatly reduced pressure given the strong optical absorption of the incident photons by ambient gases such as H₂O, O₂, etc.

As noted above, this integrated architecture is just one possible embodiment of a tool for implementation of the described processes. The processes may also be implemented with a stand-alone EUVL scanner and a deposition reactor, such as a Lam Vector tool, either stand alone or integrated in a cluster architecture with other tools, such as etch, strip etc. (e.g., Lam Kiyo or Gamma tools), as modules, for example as described with reference to FIG. 8 but without the integrated patterning module.

Airlock 842 may be an “outgoing” loadlock, referring to the transfer of a substrate out from the VTM 838 serving a deposition module 820a to the patterning module 840, and airlock 846 may be an “ingoing” loadlock, referring to the transfer of a substrate from the patterning module 840 back in to the VTM 838. The ingoing loadlock 846 may also provide an interface to the exterior of the tool for access and egress of substrates. Each process module has a facet that interfaces the module to VTM 838. For example, deposition process module 820a has facet 836. Inside each facet, sensors, for example, sensors 1-18 as shown, are used to detect the passing of wafer 826 when moved between respective stations. Patterning module 840 and airlocks 842 and 846 may be similarly equipped with additional facets and sensors, not shown.

Main VTM robot 822 transfers wafer 826 between modules, including airlocks 842 and 846. In one embodiment, robot 822 has one arm, and in another embodiment, robot 822 has two arms, where each arm has an end effector 824 to pick wafers such as wafer 826 for transport. Front-end robot 844, in is used to transfer wafers 826 from outgoing airlock 842 into the patterning module 840, from the patterning module 840 into ingoing airlock 846. Front-end robot 844 may also transport wafers 826 between the ingoing loadlock and the exterior of the tool for access and egress of substrates. Because ingoing airlock module 846 has the ability to match the environment between atmospheric and vacuum, the wafer 826 is able to move between the two pressure environments without being damaged.

It should be noted that a EUVL tool can operate at a higher vacuum than a deposition tool. If this is the case, it is desirable to increase the vacuum environment of the substrate during the transfer between the deposition to the EUVL tool to allow the substrate to degas prior to entry into the patterning tool. Outgoing airlock 842 may provide this function by holding the transferred wafers at a lower pressure, no higher than the pressure in the patterning module 840, for a period of time and exhausting any off-gassing, so that the optics of the patterning tool 840 are not contaminated by off-gassing from the substrate. A suitable pressure for the outgoing, off-gassing airlock is no more than 1E-8 Torr.

In some embodiments, a system controller 850 (which may include one or more physical or logical controllers) controls some or all of the operations of the cluster tool and/or its separate modules. It should be noted that the controller can be local to the cluster architecture, or can be located external to the cluster architecture in the manufacturing floor, or in a remote location and connected to the cluster architecture via a network. The system controller 850 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller or they may be provided over a network. In certain embodiments, the system controller executes system control software.

The system control software may include instructions for controlling the timing of application and/or magnitude of any aspect of tool or module operation. System control software may be configured in any suitable way. For example, various process tool component subroutines or control objects may be written to control operations of the process tool components necessary to carry out various process tool processes. System control software may be coded in any suitable compute readable programming language. In some embodiments, system control software includes input/output control (IOC) sequencing instructions for controlling the various parameters described above. For example, each phase of a semiconductor fabrication process may include one or more instructions for execution by the system controller. The instructions for setting process conditions for condensation, deposition, evaporation, patterning and/or etching phase may be included in a corresponding recipe phase, for example.

In various embodiments, an apparatus for forming a negative pattern mask is provided. The apparatus may include a processing chamber for patterning, deposition and etch, and a controller including instructions for forming a negative pattern mask. The instructions may include code for, in the processing chamber, patterning a feature in a chemically amplified (CAR) resist on a semiconductor substrate by EUV exposure to expose a surface of the substrate, dry developing the photopatterned resist, and etching the underlying layer or layer stack using the patterned resist as a mask.

It should be noted that the computer controlling the wafer movement can be local to the cluster architecture or can be located external to the cluster architecture in the manufacturing floor, or in a remote location and connected to the cluster architecture via a network.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of employing a resist, the method comprising:
providing an organometallic precursor in the presence of an organic co-reactant to a surface of a substrate to provide a resist film;
patterning the resist film by exposure to patterned radiation, thereby providing an exposed film having radiation exposed areas and radiation unexposed areas;
incubating the exposed film at a temperature of about 20-300° C., thereby providing an incubated film; and
developing the incubated film, thereby removing the radiation exposed areas to provide a pattern within a positive tone resist film or removing the radiation unexposed areas to provide a pattern within a negative tone resist.

2. The method of claim 1, wherein the resist film comprises an Extreme Ultraviolet (EUV)-sensitive film.

3. The method of claim 1, wherein the resist film comprises organotin acetylide oxide, tin acetylide oxide, tin acetylide telluride, organotin oxalate, tin oxalate, organotin formates, tin formates, organotin peroxides, or tin peroxides.

4. The method of claim 1, wherein a dose-to-clear or a dose-to-gel of the incubated film is lower than that of the exposed film.

5. The method of claim 1, wherein said providing comprises depositing a modified precursor on the surface of the substrate to provide the resist film, and wherein the modified precursor is formed by reacting the organometallic precursor with the organic co-reactant.

6. (canceled)

7. (canceled)

8. The method of claim 1, wherein said incubating comprises a temperature of about 100-250° C. in an ambient atmosphere for an optional time period of about 30-300 seconds.

9. The method of claim 1, wherein said incubating comprises a temperature of about 20-30° C. for a time period of about 1-7 days.

10. The method of claim 1, wherein said incubating comprises a temperature of about 150-300° C. in an inert atmosphere with an optional degree of humidity for an optional time period of about 1-300 seconds.

11. The method of claim 1, wherein said developing comprises wet development or dry development.

12. The method of claim 11, wherein the wet development comprises water, an acid, a base, a ketone, an ester, an alcohol, an ether, or a combination thereof for an optional time period of about 15-60 seconds.

13. (canceled)

14. The method of claim 11, wherein the dry development comprises gaseous water, oxygen (O₂), a gaseous acid, a gaseous halide, or a combination thereof for an optional time period of about 30-720 seconds at an optional pressure of about 0.1-1 Torr.

15. The method of claim 1, wherein said incubating comprises a temperature of about 100-250° C. in an ambient atmosphere, and wherein said developing comprises water in liquid or vapor form.

16. The method of claim 1, wherein said incubating comprises a temperature of about 20-30° C. for a time period of about 1-7 days, and wherein said developing comprises a ketone or liquid water in conjunction with a dry development process comprising water, oxygen (O₂), a gaseous acid, a gaseous halide, or a combination thereof.

17. The method of claim 1, wherein the organometallic precursor comprises at least one ligand, and wherein the organic co-reactant replaces the at least one ligand to provide a modified precursor.

18. (canceled)

19. (canceled)

20. The method of claim 1, wherein the organometallic precursor comprises a structure having formula (I):
MₐR_{b}L_{c} (I),
wherein:
M is a metal;
each R is, independently, halo, optionally substituted alkyl, optionally substituted aryl, optionally substituted amino, optionally substituted alkoxy, or L;
each L is, independently, is a ligand, ion, or other moiety that is reactive with the organic co-reactant or a counter-reactant, in which R and L with M, taken together, can optionally form a heterocyclyl group or in which R and L, taken together, can optionally form a heterocyclyl group;
a≥1; b≥1; and c≥1.

21. The method of claim 20, wherein each R is L and/or M is tin (Sn).

22. The method of claim 20, wherein each L is, independently, H, halo, optionally substituted alkyl, optionally substituted aryl, optionally substituted amino, optionally substituted bis(trialkylsilyl)amino, optionally substituted trialkylsilyl, or optionally substituted alkoxy.

23. The method of claim 1, wherein the organic co-reactant comprises one or more polymerizable moieties, alkynyl moieties, carbonyl moieties, dicarbonyl moieties, or haloalkyl moieties.

24. The method of claim 23, wherein the organic co-reactant comprises a structure having formula (II):
X¹—Z—X² (II),
wherein:
each of X¹ and X² is, independently, a leaving group; and
Z is carbonyl, dicarbonyl, optionally substituted alkylene, optionally substituted haloalkylene, optionally substituted alkenylene, or optionally substituted alkynylene.

25. (canceled)

26. The method of claim 17, wherein said providing further comprises providing a counter-reactant.

27. (canceled)

28. (canceled)

29. (canceled)

30. (canceled)

31. (canceled)

32. (canceled)

33. (canceled)

34. (canceled)

35. (canceled)

36. (canceled)
